(19) United States
(12) Patent Application Publication
(10) Pub. No.: US 2014/0368287 A1
(43) Pub. Date: Dec. 18, 2014

(54) RESONATOR ELEMENT, RESONATOR, OSCILLATOR, ELECTRONIC DEVICE, AND MOVING OBJECT

(71) Applicant: SEIKO EPSON CORPORATION, Tokyo (JP)

(72) Inventors: Akinori YAMADA, Ina-shi (JP); Osamu IWAMOTO, Chino-shi (JP)

(21) Appl. No.: 14/307,999

(22) Filed: Jun. 18, 2014

(30) Foreign Application Priority Data
Jun. 18, 2013 (JP) 2013-127980

(51) Int. Cl. H03H 9/17; H03B 5/32

(52) U.S. Cl. CPC H03H 9/17; H03B 5/32
USPC 331/156; 310/370

(57) ABSTRACT

A resonator element includes a base portion, a pair of vibrating arms that are integrally provided with the base portion and extend in a Y-axis direction from a distal end of the base portion, and a supporting arm that is integrally provided with the base portion, is positioned between the vibrating arms, and extends in the Y-axis direction from the distal end of the base portion. A first fixation portion is provided in one principal surface of the base portion, and a second fixation portion is provided in one principal surface of the supporting arm. The resonator element is fixed to an object through fixation members, by the first fixation portion and the second fixation portion.

### CROSS REFERENCE

The entire disclose of Japanese Patent Application No. 2013-127980 filed Jun. 18, 2013 is expressly incorporated by reference herein.

### BACKGROUND

1. Technical Field

The invention relates to a resonator element, a resonator, an oscillator, an electronic device, and a moving object.

2. Related Art

Hitherto, resonator elements using quartz crystal have been known. Such resonator elements have excellent frequency-temperature characteristics. Accordingly, the resonator elements are widely used as reference frequency sources, signal transmission sources, and the like of various electronic devices.

A resonator element disclosed in FIG. 1 of JP-A-2011-19159 includes a base portion and a pair of vibrating arms collaterally extending from the base portion. The resonator element is fixed to a package through conductive adhesive members by two fixation portions provided in the base portion. However, in such a configuration, there is a concern that the two fixation portions, which are disposed in the base portion in order to achieve electrical conduction and fixation, may become adjacent to and in contact with each other due to a reduction in the size of the base portion associated with a reduction in the size of the resonator element, which may result in the occurrence of a short circuit.

In addition, a resonator element disclosed in JP-A-2002-141770 includes a base portion, a pair of vibrating arms collaterally extending from the base portion, and a supporting arm extending between the pair of vibrating arms from the base portion. The resonator element is fixed to a package through conductive adhesive members by two fixation portions provided in the supporting arm. However, in such a configuration, there is a concern that the conductive adhesive members may become in contact with each other due to a short separation distance between the two fixation portions, which may result in the occurrence of a short circuit.

### SUMMARY

An advantage of some aspects of the invention is to provide a resonator element capable of reducing contact between fixation members in a state of being mounted onto an object, and a resonator, an oscillator, an electronic device, and a moving object which include the resonator element.

The invention can be implemented as the following application examples.

### Application Example 1

This application example is directed to a resonator element including a base portion; a pair of vibrating arms that extend in a first direction from one end of the base portion and are lined up in a second direction perpendicular to the first direction; and a supporting arm that extends from the base portion. A first fixation portion is provided in one principal surface of the base portion. A second fixation portion is provided in one principal surface of the supporting arm. The first fixation portion and the second fixation portion are attached to an object through fixation members.

Thus, the resonator element capable of reducing contact between the fixation members in a state of being mounted onto the object is obtained. Further, the resonator element capable of reducing vibration leakage is obtained.

### Application Example 2

This application example is directed to the resonator element according to the application example described above, wherein the supporting arm extends in the first direction from the one end of the base portion and is disposed between the pair of vibrating arms.

Thus, the resonator element capable of reducing contact between the fixation members in a state of being mounted onto an object is obtained. Further, the resonator element capable of reducing vibration leakage is obtained.

### Application Example 3

This application example is directed to the resonator element according to the application example described above, wherein the supporting arm extends from the other end on an opposite side to the one end of the base portion when seen in a plan view.

Thus, the resonator element capable of reducing contact between the fixation members in a state of being mounted onto an object is obtained. Further, the resonator element capable of reducing vibration leakage is obtained.

### Application Example 4

This application example is directed to the resonator element according to the application example described above, wherein the supporting arm includes a first portion that extends along the first direction from the other end, and a second portion that extends along the second direction from the first portion, and the second fixation portion is provided in the second portion.

Thus, since it is possible to increase a separation distance between the fixation members in a state of being mounted onto an object, the resonator element capable of reducing contact between the fixation members is obtained. Further, the resonator element capable of reducing vibration leakage is obtained.

### Application Example 5

This application example is directed to the resonator element according to the application example described above, wherein the first fixation portion intersects a virtual straight line along the first direction which passes through a center in the second direction between the pair of vibrating arms, when seen in a plan view.

Such a position is a place having a small vibration in the base portion. For this reason, the first fixation portion is provided at this position, and thus the resonator element with further reduced vibration leakage is obtained.

### Application Example 6

This application example is directed to the resonator element according to the application example described above, wherein the base portion includes a width-decreasing portion having a length along the second direction which decreases in a continuous manner or in a stepwise manner as a distance from the first fixation portion increases along the first direction, when seen in a plan view.

Thus, vibration leakage is reduced.

### Application Example 7

This application example is directed to a resonator element including a base portion; a pair of vibrating arms that extend in a first direction from one end of the base portion and are lined up in a second direction perpendicular to the first direction; a first supporting arm that extends in the first direction from the one end of the base portion and is disposed between the pair of vibrating arms; and a second supporting arm that extends from the other end on an opposite side to the one end of the base portion, when seen in a plan view. A first fixation portion is provided in one principal surface of the first supporting arm. A second fixation portion is provided in one principal surface of the second supporting arm. The first fixation portion and the second fixation portion are attached to an object through fixation members.

Thus, the resonator element capable of reducing contact between the fixation members in a state of being mounted onto the object is obtained. Further, the resonator element capable of reducing vibration leakage is obtained.

### Application Example 8

This application example is directed to the resonator element according to the application example described above, wherein the base portion includes a width-decreasing portion having a length along the second direction which decreases in a continuous manner or in a stepwise manner as a distance from the first fixation portion increases along the first direction, when seen in a plan view.

Thus, vibration leakage is reduced.

### Application Example 9

This application example is directed to a resonator including the resonator element according to the application example and a package that accommodates the resonator element.

Thus, a resonator with high reliability is obtained.

### Application Example 10

This application example is directed to an oscillator including the resonator element according to the application example and an oscillation circuit.

Thus, an oscillator with high reliability is obtained.

### Application Example 11

This application example is directed to an electronic device including the resonator element according to the application example.

Thus, an electronic device with high reliability is obtained.

### Application Example 12

This application example is directed to a moving object including the resonator element according to the application example.

Thus, a moving object with high reliability is obtained.

### BRIEF DESCRIPTION OF THE DRAWINGS

The invention will be described with reference to the accompanying drawings, wherein like numbers reference like elements.

FIG. 1 is a plan view of a resonator according to a first embodiment of the invention.

FIG. 2 is a cross-sectional view taken along line A-A of FIG. 1.

FIG. 3 is a top view of a resonator element included in the resonator shown in FIG. 1.

FIGS. 4A and 4B are plan views illustrating a function of the resonator element shown in FIG. 3.

FIG. 5 is a cross-sectional view taken along line B-B of FIG. 3.

FIG. 6 is a rear view of the resonator element shown in FIG. 3.

FIG. 7 is a cross-sectional view of a vibrating arm illustrating heat conduction during bending and vibration.

FIG. 8 is a graph showing a relationship between a Q value and f/fm of a resonator element in a bending vibration mode.

FIG. 9 is a top view of a resonator element included in a resonator according to a second embodiment of the invention.

FIG. 10 is a top view of a resonator element included in a resonator according to a third embodiment of the invention.

FIG. 11 is a top view of a resonator element included in a resonator according to a fourth embodiment of the invention.

FIG. 12 is a top view of a resonator element included in a resonator according to a fifth embodiment of the invention.

FIG. 13 is a top view of a resonator element included in a resonator according to a sixth embodiment of the invention.

FIG. 14 is a top view of a resonator element included in a resonator according to a seventh embodiment of the invention.

FIG. 15 is a top view of a resonator element included in a resonator according to an eighth embodiment of the invention.

FIG. 16 is a top view of a resonator element included in a resonator according to a ninth embodiment of the invention.

FIG. 17 is a cross-sectional view showing a preferred embodiment of an oscillator according to the invention.

FIG. 18 is a perspective view showing a configuration of a mobile (or notebook) personal computer to which an electronic device including the resonator element according to the invention is applied.

FIG. 19 is a perspective view showing a configuration of a mobile phone (PHS is also included) to which an electronic device including the resonator element according to the invention is applied.

FIG. 20 is a perspective view showing a configuration of a digital still camera to which an electronic device including the resonator element according to the invention is applied.

FIG. 21 is a perspective view schematically showing a vehicle as an example of a moving object according to the invention.

### DESCRIPTION OF EXEMPLARY EMBODIMENTS

Hereinafter, a resonator element, a resonator, an oscillator, an electronic device, and a moving object according to the invention will be described in detail with reference to preferred embodiments shown in the diagrams.

### 1. Resonator

First, the resonator according to the invention will be described.

### First Embodiment

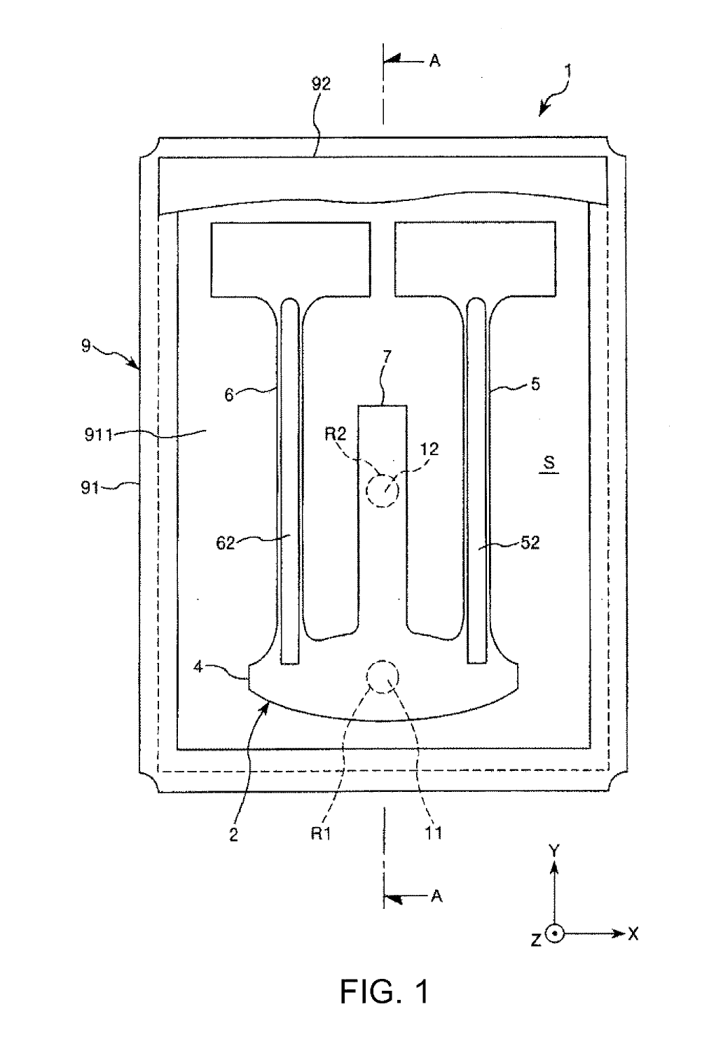

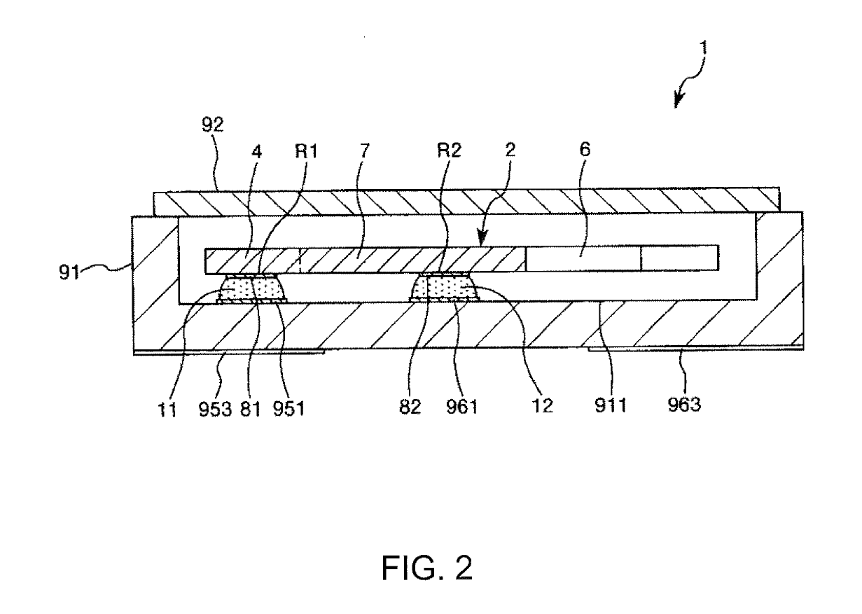

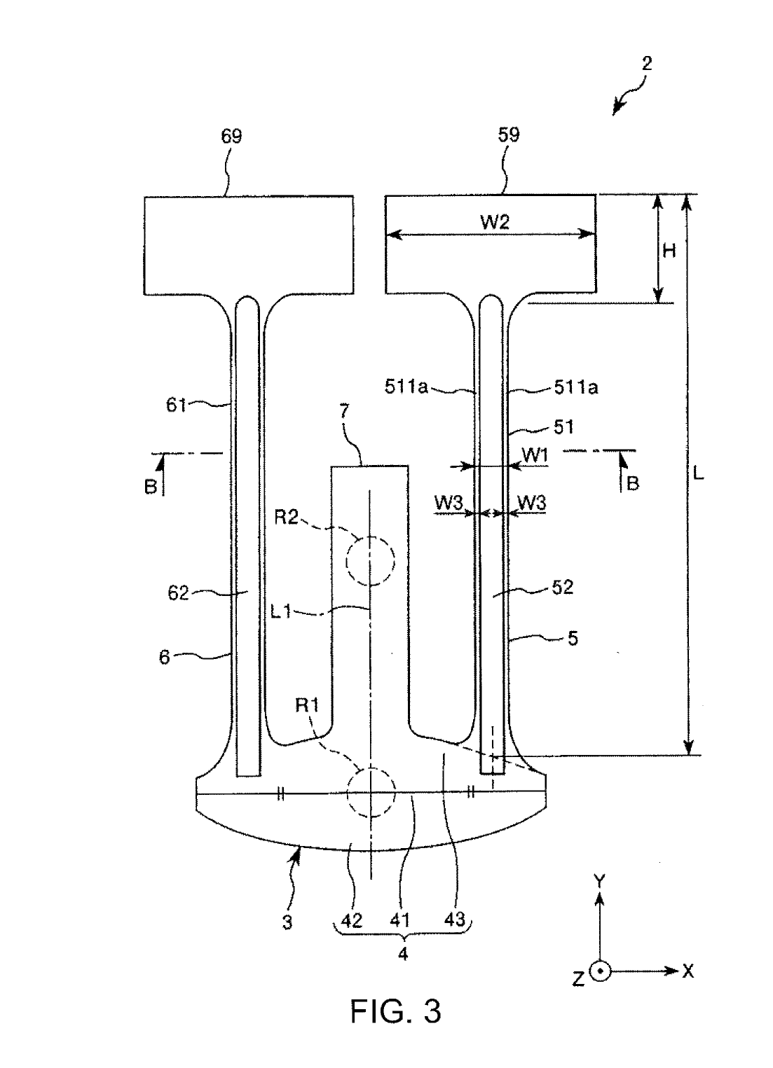

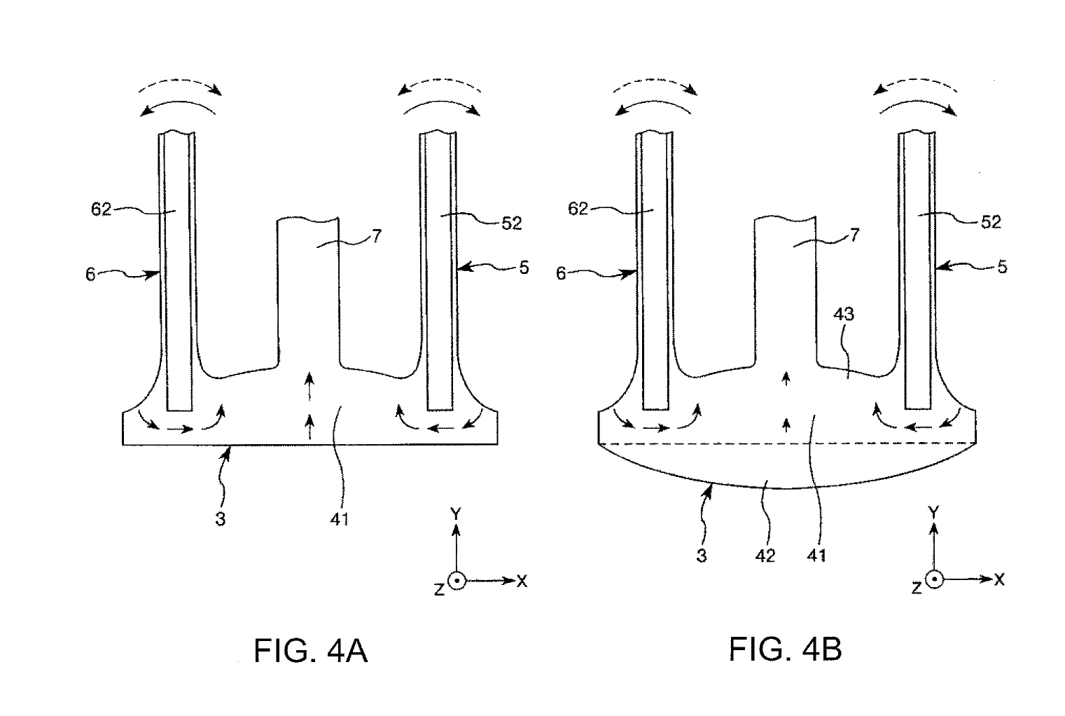

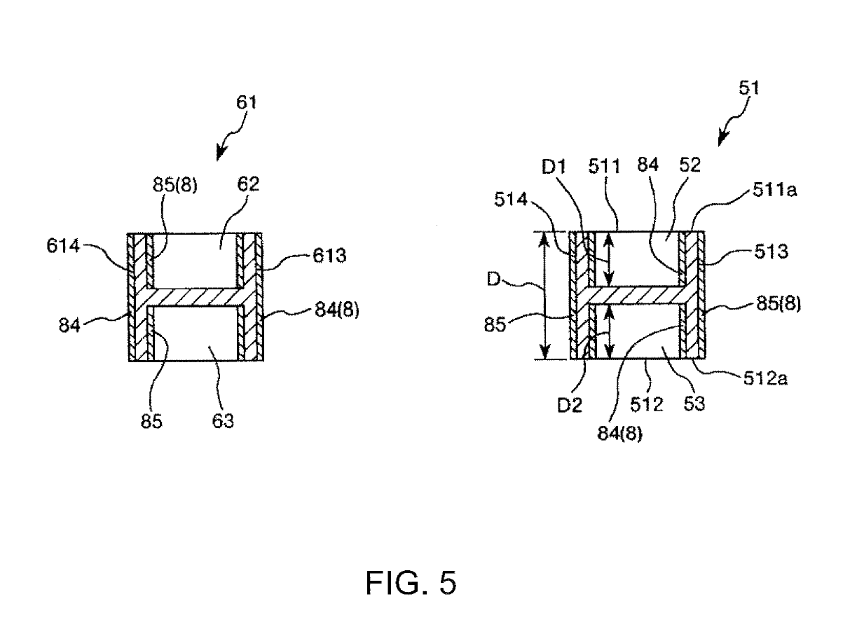

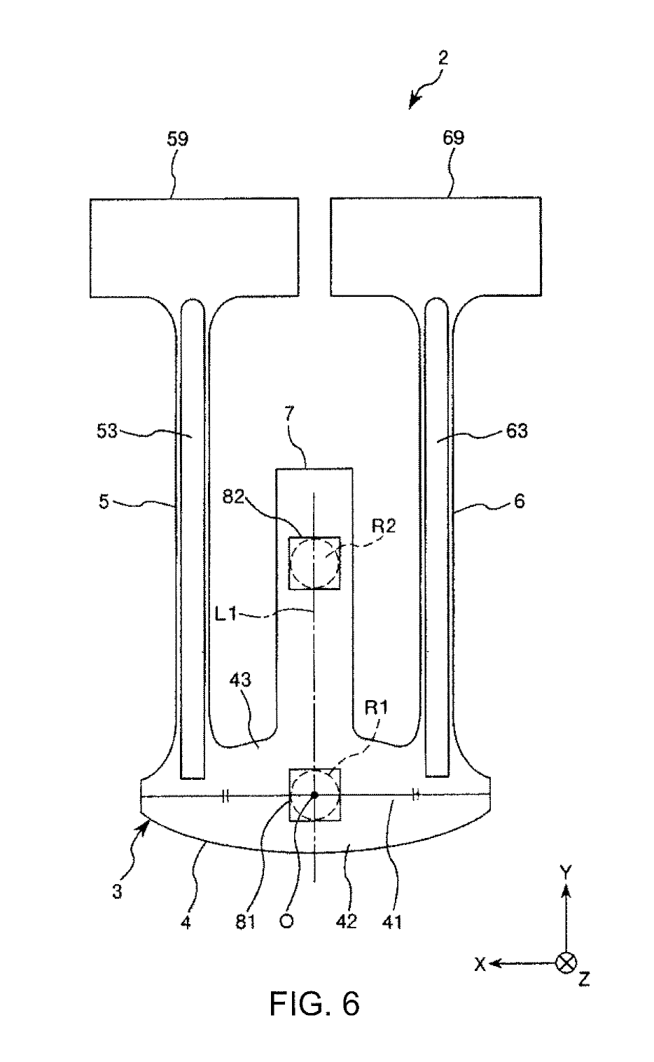

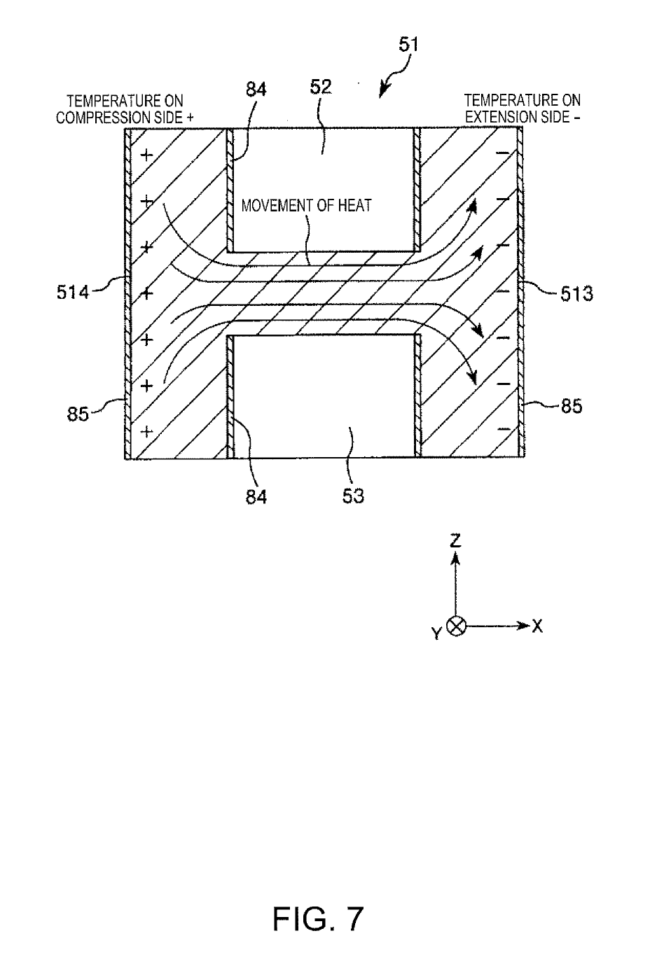

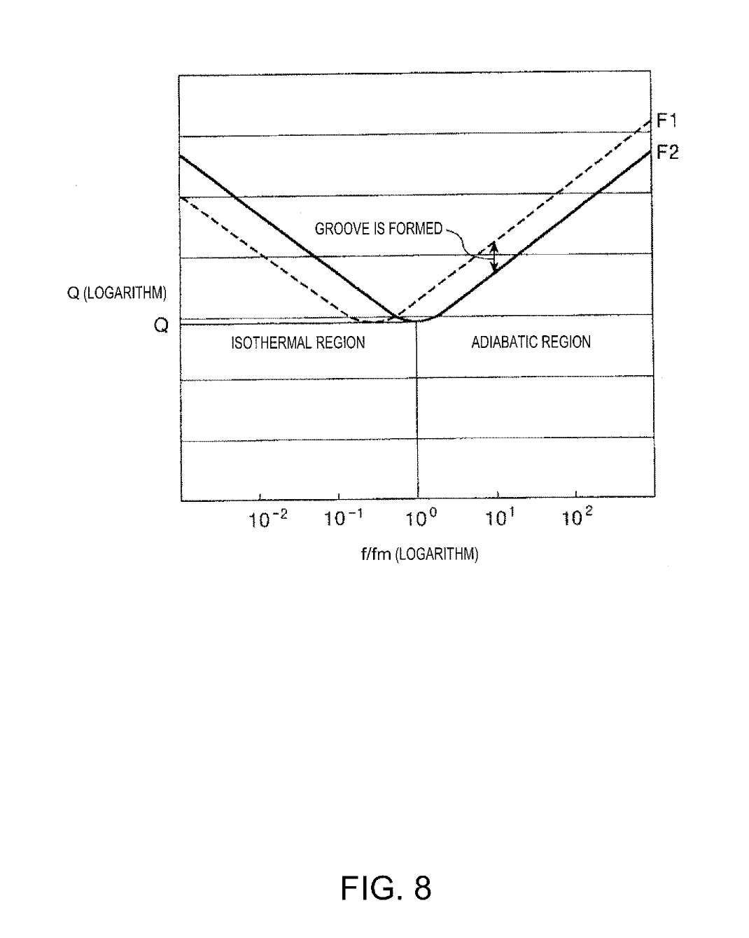

FIG. 1 is a plan view of a resonator according to a first embodiment of the invention. FIG. 2 is a cross-sectional view taken along line A-A of FIG. 1. FIG. 3 is a top view of a resonator element included in the resonator shown in FIG. 1. FIGS. 4A and 4B are plan views illustrating a function of the resonator element shown in FIG. 3. FIG. 5 is a cross-sectional view taken along line B-B of FIG. 3. FIG. 6 is a rear view of the resonator element shown in FIG. 3. FIG. 7 is a cross-sectional view of a vibrating arm illustrating heat conduction during bending and vibration. FIG. 8 is a graph showing a relationship between a Q value and f/fm. Meanwhile, as shown in FIG. 1, three axes perpendicular to each other are assumed to be an X-axis (electrical axis of quartz crystal), a Y-axis (mechanical axis of quartz crystal), and a Z-axis (optical axis of quartz crystal) hereinbelow for convenience of description. In FIG. 2, an upper side is set to a “top (front)” and a lower side is set to a “bottom (back)”. In FIG. 3, an upper side is set to a “distal end” and a lower side is set to a “base end”.

As shown in FIG. 1, a resonator 1 includes a resonator element (resonator element according to the invention) 2 and a package 9 that accommodates the resonator element 2.

### Package

As shown in FIGS. 1 and 2, the package 9 includes a box-shaped base 91 having a concave portion 911, which is opened on the top surface, and a plate-shaped lid 92 bonded to the base 91 so as to close the opening of the concave portion 911. The package 9 has an accommodation space S formed by closing the concave portion 911 with the lid 92, and the resonator element 2 is accommodated in the accommodation space S in an airtight manner. The accommodation space S may be in a decompressed (preferably, vacuum) state, or may be filled with inert gas such as nitrogen, helium, and argon.

A material of the base 91 is not particularly limited, and various ceramics such as aluminum oxide can be used. In addition, although a material of the lid 92 is not particularly limited, it is preferable to use a member having a linear expansion coefficient similar to that of the material of the base 91. For example, when the above-described ceramic is used as a material of the base 91, it is preferable to use an alloy such as Kovar. Meanwhile, the bonding of the base 91 and the lid 92 is not particularly limited. For example, the base and the lid may be bonded to each other through a metalization layer.

In addition, connecting terminals 951 and 961 are formed on the bottom surface of the concave portion 911 of the base 91. A first conductive adhesive member (fixation member) 11 is provided on the connecting terminal 951, and a second conductive adhesive member (fixation member) 12 is provided on the connecting terminal 961. The resonator element 2 is fixed to the base 91 through the first and second conductive adhesive members 11 and 12. Meanwhile, materials of the first and second conductive adhesive members 11 and 12 are not particularly limited as long as the materials have conductive, adhesive, and bonding properties. For example, a conductive adhesive member including a silicone-based, epoxy-based, acrylic-based, polyimide-based, bismaleimide-based, polyester-based, or polyurethane-based resin mixed with a conductive filler such as silver particles, or a metal material such as Au can be used.

In addition, the connecting terminal 951 is electrically connected to an external terminal 953, provided on the bottom surface of the base 91, through a through electrode (not shown) passing through the base 91. Similarly, the connecting terminal 961 is electrically connected to an external terminal 963, provided on the bottom surface of the base 91, through a through electrode (not shown) passing through the base 91. Materials of the connecting terminals 951 and 961, the external terminals 953 and 963, and the through electrode are not particularly limited as long as the materials have conductivity. For example, the terminals and the electrode can be formed of a metal coating in which a coat such as gold (Au), silver (Ag), or copper (Cu) is laminated on a base layer such as chromium (Cr), nickel (Ni), or tungsten (W).

### Resonator Element

As shown in FIGS. 3 to 5, the resonator element 2 includes a quartz crystal substrate 3 and an electrode 8 formed on the quartz crystal substrate 3.

The quartz crystal substrate 3 is constituted by a Z-cut quartz crystal plate. The Z-cut quartz crystal plate refers to a quartz crystal substrate using a Z-axis as its thickness direction. Meanwhile, it is preferable that the Z-axis conforms with the thickness direction of the quartz crystal substrate 3. However, from the viewpoint of reducing a change in frequency with temperature near room temperature, the Z-axis may be inclined slightly (for example, approximately less than 15 degrees) with respect to the thickness direction.

That is, it is assumed that the X-axis of a rectangular coordinate system constituted by the X-axis as the electrical axis of quartz crystal, the Y-axis as the mechanical axis thereof, and the Z-axis as the optical axis thereof is a rotation axis. When an axis obtained by inclining the Z-axis so that a +Z side rotates in the −Y direction of the Y-axis is set to a Z′-axis and an axis obtained by inclining the Y-axis so that a +Y side rotates in the +Z direction of the Z-axis is set to a Y′-axis, the quartz crystal substrate 3 is obtained in which a direction along the Z′-axis is set to the thickness thereof and a surface including the X-axis and the Y′-axis is set to the principal surface thereof.

Meanwhile, the thickness D of the quartz crystal substrate 3 is not particularly limited, but is preferably less than 70 μm. Based on such a numerical range, when the quartz crystal substrate 3 is formed (patterned) by, for example, wet etching, it is possible to effectively prevent unnecessary portions (portions necessary to be removed) from remaining in a boundary between a vibrating arm 5 and a base portion 4, a boundary between an arm portion 51 to be described later and a hammerhead 59 as a weight portion, and the like. For this reason, it is possible to obtain the resonator element 2 capable of effectively reducing vibration leakage. From a different point of view, the thickness D is preferably equal to or greater than 70 μm and equal to or less than 300 μm, and more preferably equal to or greater than 100 μm and equal to or less than 150 μm. Based on such a numerical range, it is possible to form first and second driving electrodes 84 and 85 to be described later to be wide in the side surfaces of the vibrating arm 5 and a vibrating arm 6, and thus it is possible to lower a CI value.

As shown in FIG. 3, the quartz crystal substrate 3 includes the base portion 4, the pair of vibrating arms (first, second vibrating arm) 5 and 6 extending in the +Y-axis direction (first direction) from the distal end (one end) of the base portion 4, and a supporting arm 7 extending in the +Y-axis direction from the distal end of the base portion 4. The base portion 4, the vibrating arms 5 and 6, and the supporting arm 7 are integrally formed from the quartz crystal substrate 3.

The base portion 4 has a substantially plate shape that extends on the XY plane and has a thickness in the Z-axis direction. The base portion 4 includes a portion (main body 41), which supports and connects the vibrating arms 5 and 6, and width-decreasing portions 42 and 43 to reduce vibration leakage.

The width-decreasing portion 42 is provided on the base end side (side opposite to a side on which the vibrating arms 5 and 6 extend) of the main body 41. In addition, the width (length along the X-axis direction) of the width-decreasing portion 42 gradually decreases as a distance from each of the vibrating arms 5 and 6 increases. Due to the width-decreasing portion 42, it is possible to effectively reduce the vibration leakage of the resonator element 2.

This will be specifically described as follows. Meanwhile, in order to simplify the description, it is assumed that the shape of the resonator element 2 is symmetrical about a predetermined axis parallel to the Y-axis.

First, as shown in FIG. 4A, a case where the width-decreasing portion 42 is not provided will be described. As will be described later, when the vibrating arms 5 and 6 bend and deform so as to separate from each other, displacement close to clockwise rotational movement occurs as indicated by the arrow in the main body 41 in the vicinity to which the vibrating arm 5 is connected, and displacement close to counterclockwise rotational movement occurs as indicated by the arrow in the main body 41 in the vicinity to which the vibrating arm 6 is connected (however, strictly speaking, this movement cannot be said to be rotational movement, and accordingly, this is expressed as “being close to rotational movement” for convenience). Since X-axis direction components of these displacements are in the directions opposite to each other, the X-axis direction components are offset in the X-axis direction central portion of the main body 41, and displacement in the +Y-axis direction remains (however, strictly speaking, displacement in the Z-axis direction also remains, but the displacement in the Z-axis direction will be omitted herein). That is, the main body 41 bends and deforms such that the X-axis direction central portion is displaced in the +Y-axis direction. When a binding material is formed in a Y-axis direction central portion of the main body 41 having the displacement in the +Y-axis direction and is fixed to the package through the binding material, elastic energy due to the displacement in the +Y-axis direction leaks to the outside through the binding material. This is loss of vibration leakage, causing the degradation of the Q value. As a result, the CI value is degraded.

In contrast, as shown in FIG. 4B, when the width-decreasing portion 42 is provided, the width-decreasing portion 42 has an arch-shaped (curved) contour. For this reason, the displacements close to the rotational movement described above are superimposed on each other in the width-decreasing portion 42. That is, in the X-axis direction central portion of the width-decreasing portion 42, displacements in the X-axis direction are offset as in the X-axis direction central portion of the main body 41, and the displacement in the Y-axis direction is also suppressed. In addition, since the contour of the width-decreasing portion 42 has an arch shape, the displacement in the +Y-axis direction that will occur in the main body 41 is also suppressed. As a result, the displacement in the +Y-axis direction of the X-axis direction central portion of the base portion 4 when the width-decreasing portion 42 is provided becomes much smaller than that when the width-decreasing portion 42 is not provided. That is, it is possible to obtain a resonator element having small vibration leakage.

On the other hand, the width-decreasing portion 43 is provided on the distal end side (side on which the vibrating arms 5 and 6 extend) of the main body 41. In addition, the width (length along the X-axis direction) of the width-decreasing portion 43 gradually decreases in the +Y-axis direction. Due to the width-decreasing portion 43, it is possible to effectively suppress the vibration leakage of the resonator element 2. The width-decreasing portion 43 is positioned between the main body 41 and the supporting arm 7. Accordingly, vibrations of the vibrating arms 5 and 6 are not likely to be transmitted to the supporting arm 7 through the base portion 4, and thus it is possible to effectively suppress vibration leakage. Specifically, as described above, the vibrations of the vibrating arms 5 and 6 are offset (reduced and absorbed) mainly by the width-decreasing portion 42, but the vibration that cannot be wholly offset by the width-decreasing portion 43 may move toward the supporting arm (see FIG. 4B). In this case, since the vibration can be reduced and absorbed by the width-decreasing portion 43, it is possible to further efficiently reduce vibration leakage.

Meanwhile, in this embodiment, the contours of the width-decreasing portions 42 and 43 have an arch shape, but are not limited thereto as long as the width-decreasing portions exhibit the above-described effects. For example, the width-decreasing portions may be width-decreasing portions having a contour that is formed stepwise by a plurality of straight lines. In other words, the width-decreasing portions may have a structure in which the width of the width-decreasing portion along the X-axis direction (second direction) stepwise decreases.

The vibrating arms 5 and 6 extend in the +Y-axis direction (first direction) from the distal end of the base portion 4 so as to be lined up in the X-axis direction (second direction) and parallel to each other. Each of the vibrating arms 5 and 6 has an elongated shape. The base end of each of the vibrating arms is a fixed end, and the distal end is a free end.

In addition, the vibrating arms 5 and 6 include arm portions 51 and 61 and hammerheads 59 and 69 as weight portions provided at the distal ends of the arm portions 51 and 61. Meanwhile, since the vibrating arms 5 and 6 have the same configuration, the vibrating arm 5 will be described as a representative vibrating arm hereinafter, and description of the vibrating arm 6 will be omitted.

As shown in FIG. 5, the arm portion 51 has a pair of principal surfaces 511 and 512 which are the XY plane, and a pair of side surfaces 513 and 514 which are the YZ plane and connect the pair of principal surfaces 511 and 512 to each other. In addition, the arm portion 51 includes a bottomed groove 52 opened to the principal surface 511 and a bottomed groove 53 opened to the principal surface 512. Each of the grooves 52 and 53 extends in the Y-axis direction, its distal end extends up to the hammerhead 59, and its base end extends up to the base portion 4. In this manner, when the distal end of each of the grooves 52 and 53 extends up to the hammerhead 59, stress concentration occurring near the distal end of each of the grooves 52 and 53 is reduced. Therefore, a possibility of chipping or breakage that occurs when an impact is applied is reduced. In addition, when the base end of each of the grooves 52 and 53 extends up to the base portion 4, stress concentration occurring near the boundary between the vibrating arm 5 and the base portion 4 is reduced. For this reason, for example, a possibility of chipping or breakage that occurs when an impact is applied is reduced.

Although the depth of each of the grooves 52 and 53 is not particularly limited, it is preferable that the relation of 60%≦(D1+D2)/D≦95% is satisfied assuming that the depth of the groove 52 is D1 and the depth of the groove 53 is D2 (in this embodiment, D1=D2). Since a heat transfer path becomes longer by satisfying such a relationship, it is possible to more effectively reduce thermoelastic loss in an adiabatic region (to be described later in detail).

Meanwhile, it is preferable to form the grooves 52 and 53 by adjusting the positions of the grooves 52 and 53 in the X-axis direction with respect to the position of the vibrating arm 5 so that the cross-sectional centroid of the vibrating arm 5 matches the center of the cross-sectional shape of the vibrating arm 5. In this manner, since it is possible to reduce an unnecessary vibration (specifically, an oblique vibration having an out-of-plane component) of the vibrating arm 5, it is possible to reduce vibration leakage. In this case, since it is also possible to reduce driving for an unnecessary vibration, a driving region is relatively increased. Therefore, it is possible to reduce the CI value.

In addition, assuming that the widths (lengths in the X-axis direction) of bank portions (principal surfaces lined up with the groove 52 interposed therebetween along the width direction perpendicular to the longitudinal direction of the vibrating arm) 511a, which are positioned on both sides of the groove 52 of the principal surface 511 in the X-axis direction, and bank portions 512a, which are positioned on both sides of the groove 53 of the principal surface 512 in the X-axis direction, are W3, it is preferable to satisfy the relation of 0 μm<W3≦20 μm. In this manner, the CI value of the resonator element 2 becomes sufficiently low. In the numerical range described above, it is preferable to satisfy the relation of 5 μm<W3≦9 μm. In this manner, in addition to the effects described above, it is possible to reduce thermoelastic loss. In addition, it is also preferable to satisfy the relation of 0 μm<W3≦5 μm. In this manner, it is possible to further lower the CI value of the resonator element 2.

The hammerhead 59 has a substantially rectangular shape in which the X-axis direction is a longitudinal direction when seen in a plan view. The hammerhead 59 has a width (length in the X-axis direction) which is greater than that of the arm portion 51, and protrudes to both sides in the X-axis direction from the arm portion 51. By forming the hammerhead 59 in such a configuration, it is possible to increase the mass of the hammerhead 59 while suppressing the total length L of the vibrating arm 5. In other words, when the total length L of the vibrating arm 5 is fixed, it is possible to secure the arm portion 51 being as long as possible without reducing the mass effect of the hammerhead 59. For this reason, it is possible to increase the width of the vibrating arm 5 in order to obtain a desired resonance frequency (for example, 32.768 kHz). As a result, since a heat transfer path to be described later becomes longer, thermoelastic loss is reduced and the Q value is improved.

In addition, the center of the hammerhead 59 in the X-axis direction may be slightly shifted from the center of the vibrating arm 5 in the X-axis direction. In this manner, since a vibration of the base portion 4 in the Z-axis direction which may occur due to the torsion of the vibrating arm 5 during bending and vibration can be reduced, it is possible to suppress vibration leakage.

In addition, when the total length (length in the Y-axis direction) of the vibrating arm 5 is set to L and the length (length in the Y-axis direction) of the hammerhead 59 is set to H, it is preferable that the vibrating arm 5 satisfies the relation of 1.2%<H/L<30.0% and satisfies the relation of 4.6%<H/L<22.3%. When such a numerical range is satisfied, the CI value of the resonator element 2 is low. Therefore, the vibration loss is small, and the resonator element 2 having an excellent vibration characteristics is obtained. Here, in this embodiment, the base end of the vibrating arm 5 is set in a position of the line segment, which connects a place where the side surface 514 is connected to the base portion 4 and a place where the side surface 513 is connected to the base portion 4, in the center of the width (length in the X-axis direction) of the vibrating arm 5. In addition, the base end of the hammerhead 59 is set in a position where the width thereof is 1.5 times the width of the arm portion 51, in a tapered portion provided in the distal end of the arm portion 51.

In addition, when the width (length in the X-axis direction) of the arm portion 51 is set to W1 and the width (length in the X-axis direction) of the hammerhead 59 is set to W2, it is preferable that the relation of 1.5≦W2/W1≦10.0 is satisfied, and it is more preferable that the relation of 1.6≦W2/W1≦7.0 is satisfied. By satisfying such a numerical range, it is possible to secure a large width for the hammerhead 59. For this reason, even if the length H of the hammerhead 59 is relatively small as described above, it is possible to sufficiently exhibit the mass effect of the hammerhead 59.

Meanwhile, by setting L≦2 mm, preferably, L≦1 mm, it is possible to obtain a small resonator element used in an oscillator that is mounted in a portable music device, an IC card, and the like. In addition, by setting W1≦100 μm, preferably, W1≦50 μm, it is also possible to obtain a resonator element, which resonates at a low frequency and which is used in an oscillation circuit for realizing low power consumption, in the range of L described above. In addition, in the case of an adiabatic region, when the vibrating arms 5 and 6 extend in the Y-axis direction in the quartz crystal Z plate and bend and vibrate in the X direction as in this embodiment, it is preferable that W1≧12.8 μm is satisfied. When the vibrating arms 5 and 6 extend in the X direction in the quartz crystal Z plate and bend and vibrate in the Y direction, it is preferable that W1≧14.4 μm is satisfied. When the vibrating arms 5 and 6 extend in the Y direction in the quartz crystal X plate and bend and vibrate in the Z direction, it is preferable that W1≧15.9 μm is satisfied. In this manner, since an adiabatic region can be reliably obtained, thermoelastic loss is reduced by the formation of the grooves 52, 53, 62, and 63, and the Q value is improved. In addition, due to driving in a region where the grooves 52, 53, 62, and 63 are formed, the electric field efficiency is high, and the driving area is secured. Accordingly, the CI value is reduced.

Meanwhile, the hammerheads 59 and 69 as weight portions are configured as wide width portions having a length along the X-axis direction which is larger than those of the arm portions 51 and 61. However, the invention is not limited thereto, and the hammerheads may have a mass density per unit length which is greater than those of the arm portions 51 and 61. For example, the weight portions may be configured to have a length that is the same as the lengths of the arm portions 51 and 61 along the X-axis direction and to have a thickness along the Z-axis direction which is larger than that of the arm portions. In addition, the weight portions may be configured such that a metal such as Au is provided thickly on each of the surfaces of the arm portions 51 and 61 which correspond to the weight portions. Further, the weight portions may be formed of a material having a higher mass density than those of the arm portions 51 and 61.

The supporting arm 7 is positioned between the vibrating arms 5 and 6, and extends in the +Y-axis direction from the distal end of the base portion 4. In addition, the distal end of the supporting arm 7 is positioned on the base portion 4 side with respect to the base ends of the hammerheads 59 and 69. Thus, since it is possible to make the vibrating arms 5 and 6 approach each other, it is possible to reduce the size of the resonator element 2.

Until now, the contour of the quartz crystal substrate 3 has been described. As shown in FIGS. 2, 3 and 6, the quartz crystal substrate 3 includes a first fixation portion R1 and a second fixation portion R2. The quartz crystal substrate is attached to the base 91 (package 9) which is an object through the conductive adhesive members 11 and 12 as fixation members, by the first and second fixation portions R1 and R2.

The first fixation portion R1 is provided in one principal surface (surface on the −Z-axis side) of the base portion 4 and at the X-axis direction central portion of the main body 41. In other words, the first fixation portion R1 (in particular, the center of the first fixation portion R1) is positioned on a straight line L1 which intersects a center O (in other words, a center point between the vibrating arms 5 and 6) of the base portion 4 in the width direction and which is parallel to the Y-axis, when seen in a plan view. This place is a place having a small vibration due to the mutual offset between the vibrations of the vibrating arms 5 and 6, as described above. For this reason, it is possible to effectively reduce vibration leakage through the conductive adhesive member 11 by providing the first fixation portion R1 in this place. It is particularly preferable that the first fixation portion R1 is positioned at the main body 41 in the base portion 4.

The second fixation portion R2 is provided in one principal surface (surface on the −Z-axis side) of the supporting arm 7. As described above, the vibrations of the vibrating arms 5 and 6 are not likely to be transmitted to the supporting arm 7 due to the width-decreasing portions 42 and 43 of the base portion 4. For this reason, it is possible to effectively reduce vibration leakage through the conductive adhesive member 12 by providing the second fixation portion R2 in the supporting arm 7. In particular, it is preferable that the second fixation portion R2 is provided and lined up with the first fixation portion R1 in the Y-axis direction. That is, it is preferable that the second fixation portion R2 (in particular, the center of the second fixation portion R2) is provided on the straight line L1. In this manner, the first and second fixation portions R1 and R2 are provided and lined up along the straight line L1, and thus it is possible to fix the resonator element 2 to the base 91 in a balanced manner. Further, it is preferable that a distance, when seen in a plan view, between a line segment, which connects the center of the first fixation portion R1 and the center of the second fixation portion R2, and the centroid of the resonator element 2 is equal to or less than half a distance between a center line, which passes through the center of the width (length in the X-axis direction) of the vibrating arm 5 and is parallel to the Y-axis, and a center line which passes through the center of the width of the vibrating arm 6 and is parallel to the Y-axis. In this manner, it is possible to fix the resonator element 2 to the base 91 in a more balanced manner.

In this embodiment, the first fixation portion R1 is provided on the straight line L1 on the base portion 4, and the second fixation portion R2 is provided in the supporting arm 7, and thus both the first and second fixation portions R1 and R2 are provided in regions having a small vibration. As a result, the resonator 1 with little vibration leakage is obtained. In addition, since the first fixation portion R1 and the second fixation portion R2 can be disposed so as to be sufficiently spaced apart from each other, it is possible to prevent contact (short circuit) between the conductive adhesive members 11 and 12. Meanwhile, the separation distance between the first and second fixation portions R1 and R2 is not particularly limited. For example, the separation distance is preferably equal to or greater than 50 μm and is more preferably equal to or greater than 100 μm. Thus, it is possible to further effectively prevent contact between the conductive adhesive members 11 and 12.

In addition, it is preferable that the Young's modulus of the first fixation portion R1 is smaller than the Young's modulus of the second fixation portion R2. In this manner, it is possible to keep a resonance frequency in an X common mode (unnecessary vibration mode) away from a resonance frequency in an x reverse phase mode (main mode).

The electrode 8 includes a first driving electrode 84, a second driving electrode 85, a first connection electrode 81 connected to the first driving electrode 84, and a second connection electrode 82 connected to the second driving electrode 85.

As shown in FIG. 5, the vibrating arm 5 is provided with a pair of first driving electrodes 84 and a pair of second driving electrode 85. One of the pair of first driving electrodes 84 is formed on the side surface of the groove 52, and the other is formed on the side surface of the groove 53. In addition, one of the pair of second driving electrodes 85 is formed on the side surface 513, and the other is formed on the side surface 514. Similarly, the vibrating arm 6 is also provided with a pair of first driving electrodes 84 and a pair of second driving electrodes 85. One of the pair of first driving electrodes 84 is formed on a side surface 613, and the other is formed on a side surface 614. In addition, one of the pair of second driving electrodes 85 is formed on the side surface of the groove 62, and the other is formed on the side surface of the groove 63.

In addition, as shown in FIG. 6, the first connection electrode 81 is provided in the first fixation portion R1, and is electrically connected to the first driving electrodes 84 through a wiring not shown in the drawing. In addition, the second connection electrode 82 is provided in the second fixation portion R2, and is electrically connected to the second driving electrodes 85 through a wiring not shown in the drawing. For this reason, the first connection electrode 81 is electrically connected to the connecting terminal 951 through the conductive adhesive member 11, and the second connection electrode 82 is electrically connected to the connecting terminal 961 through the conductive adhesive member 12. When an alternating voltage is applied between the first and second connection electrodes 81 and 82, the vibrating arms 5 and 6 vibrate with a predetermined frequency in an in-plane direction (X-axis direction) so that the vibrating arms alternately repeat mutual approach and separation substantially within a plane. That is, the vibrating arms 5 and 6 vibrate in a so-called X reverse phase mode.

Materials of the first and second driving electrodes 84 and 85 and the first and second connection electrodes 81 and 82 are not particularly limited. The electrodes can be formed of a metal material such as gold (Au), a gold alloy, platinum (Pt), aluminum (Al), an aluminum alloy, silver (Ag), a silver alloy, chromium (Cr), a chromium alloy, nickel (Ni), a nickel alloy, copper (Cu), molybdenum (Mo), niobium (Nb), tungsten (W), iron (Fe), titanium (Ti), cobalt (Co), zinc (Zn), or zirconium (Zr), or a conductive material such as indium tin oxide (ITO).

As specific configurations of the first and second driving electrodes 84 and 85 and the first and second connection electrodes 81 and 82, a configuration can be adopted in which an Au layer of equal to or less than 700 Å is formed on a Cr layer of equal to or less than 700 Å, for example. In particular, since Cr and Au have a great thermoelastic loss, the Cr layer and the Au layer are preferably set to equal to or less than 200 Å. When insulation breakdown resistance is increased, the Cr layer and the Au layer are preferably set to equal to or greater than 1000 Å. Further, since Ni has a thermal expansion coefficient close to that of quartz crystal, thermal stress caused by electrodes is reduced by using a Ni layer as a foundation layer in place of the Cr layer, and thus it is possible to obtain a resonator element with a good long-term reliability (aging characteristics).

Until now, the resonator element 2 has been described. As described above, in the resonator element 2, the grooves 52 and 53 and the grooves 62 and 63 are formed in the vibrating arm 5 and the vibrating arm 6 to reduce thermoelastic loss. Hereinafter, this will be described concretely below by using the vibrating arm 5 as an example.

As described above, the vibrating arm 5 bends and vibrates substantially in the in-plane direction by applying an alternating voltage between the first and second driving electrodes 84 and 85. As shown in FIG. 7, at the time of the bending and vibration of the vibrating arm, the side surface 514 expands when the side surface 513 of the arm portion 51 contracts. In contrast, the side surface 514 contracts when the side surface 513 expands. When the vibrating arm 5 does not cause the Gough-Joule effect (when energy elasticity is dominant over the entropy elasticity), the temperature on the contracted surface side of the side surfaces 513 and 514 rises, and the temperature on the expanded surface side thereof drops. For this reason, a difference in temperature occurs between the side surface 513 and the side surface 514, in other words, inside the arm portion 51. Due to heat conduction resulting from the difference in temperature, loss of vibration energy occurs. As a result, the Q value of the resonator element 2 is reduced. The reduction in the Q value is also referred to as a thermoelastic effect, and the loss of energy due to the thermoelastic effect is also referred to as thermoelastic loss.

In a resonator element that vibrates in a bending vibration mode and has the same configuration as the resonator element 2, when a bending vibration frequency (mechanical bending vibration frequency) f of the vibrating arm 5 changes, the Q value is minimized when the bending vibration frequency of the vibrating arm 5 conforms with a thermal relaxation frequency fm. The thermal relaxation frequency fm can be calculated by an expression of fm=1/(2πτ) (where, in the expression, π denotes the circular constant, and τ denotes a relaxation time required for a difference in temperature to become e⁻¹ times by heat conduction, assuming that e is Napier's constant).

In addition, if a thermal relaxation frequency of a flat plate structure (structure having a rectangular cross-sectional shape) is fm0, fm0 can be calculated by the following expression.

fm0=πk/(2ΣCpa²) (1)

Meanwhile, π is the circular constant, k is the thermal conductivity of the vibrating arm 5 in the vibration direction (X-axis direction), ρ is the mass density of the vibrating arm 5, Cp is the heat capacity of the vibrating arm 5, and a is the width of the vibrating arm 5 in the vibration direction. When the constants of the material itself (that is, quartz crystal) of the vibrating arm 5 are input as the thermal conductivity k, the mass density ρ, and the heat capacity Cp in Expression (1), the calculated thermal relaxation frequency fm0 is a value when the grooves 52 and 53 are not provided in the vibrating arm 5.

In the vibrating arm 5, the grooves 52 and 53 are formed so as to be positioned between the side surfaces 513 and 514. For this reason, since a heat transfer path for balancing a difference in temperature between the side surfaces 513 and 514, which is caused when the vibrating arm 5 bends and vibrates, is formed by heat conduction so as to bypass the grooves 52 and 53, the heat transfer path thus becomes longer than a straight-line distance (shortest distance) between the side surfaces 513 and 514. Therefore, the relaxation time τ becomes longer and the thermal relaxation frequency fm becomes lower, as compared with a case where the grooves 52 and 53 are not provided in the vibrating arm 5.

FIG. 8 is a graph showing f/fm dependence of the Q value of the resonator element in the bending vibration mode. In FIG. 8, a curve F1 shown by a dotted line indicates a case where a groove is formed in a vibrating arm as in the resonator element 2, and a curve F2 shown by a solid line indicates a case where a groove is not formed in a vibrating arm. As shown in FIG. 8, the shapes of the curves F1 and F2 are not changed, but the curve F1 is shifted in a frequency decrease direction with respect to the curve F2 in association with a reduction in the thermal relaxation frequency fm mentioned above. Accordingly, assuming that the thermal relaxation frequency when a groove is formed in a vibrating arm as in the resonator element 2 is fm1, the Q value of the resonator element in which a groove is formed in the vibrating arm is always higher than the Q value of the resonator element in which a groove is not formed in the vibrating arm by the following Expression (2) being satisfied.

f>\sqrt{fₘ₀fₘ₁} (2)

Further, it is possible to obtain a higher Q value when being limited to the relation of f/fm₀>1.

Meanwhile, in FIG. 8, the region of f/fm<1 is also referred to as an isothermal region. In this isothermal region, the Q value increases as f/fm decreases. This is because the above-described difference in temperature within the vibrating arm is not likely to occur as the mechanical frequency of the vibrating arm becomes low (vibration of the vibrating arm becomes slow). Accordingly, at a limit when f/fm approaches infinitely 0 (zero), an isothermal quasi-static operation is realized, and thus thermoelastic loss approaches infinitely 0 (zero). On the other hand, the region of f/fm>1 is also referred to as an adiabatic region. In this adiabatic region, the Q value increases as f/fm increases. This is because the switching of temperature rise and temperature effect of each side surface becomes fast as the mechanical frequency of the vibrating arm becomes high, and accordingly, there is no time in which the above-described heat conduction occurs. Accordingly, at a limit when f/fm is increased approaching infinity, an adiabatic operation is realized, and thus thermoelastic loss approaches infinitely 0 (zero). In other words, from this, f/fm is in the adiabatic region if the relation of f/fm>1 is satisfied.

Here, since the materials (metal materials) of the first and second driving electrodes 84 and 85 have higher thermal conductivity than quartz crystal which is the material of the vibrating arms 5 and 6, heat conduction through the first driving electrode 84 is actively performed in the vibrating arm 5 and heat conduction through the second driving electrode 85 is actively performed in the vibrating arm 6. When such heat conduction through the first and second driving electrodes 84 and 85 is actively performed, the relaxation time t is shortened. Consequently, as shown in FIG. 5, the first driving electrode 84 is divided into the side surface 513 side and the side surface 514 side at the bottom surfaces of the grooves 52 and 53 in the vibrating arm 5, and the second driving electrode 85 is divided into the side surface 613 side and the side surface 614 side at the bottom surfaces of the grooves 62 and 63 in the vibrating arm 6, thereby reducing the above-described heat conduction. As a result, it is possible to prevent the relaxation time τ from being shortened, and thus the resonator element 2 having a higher Q value is obtained.

### Second Embodiment

Next, a resonator according to a second embodiment of the invention will be described.

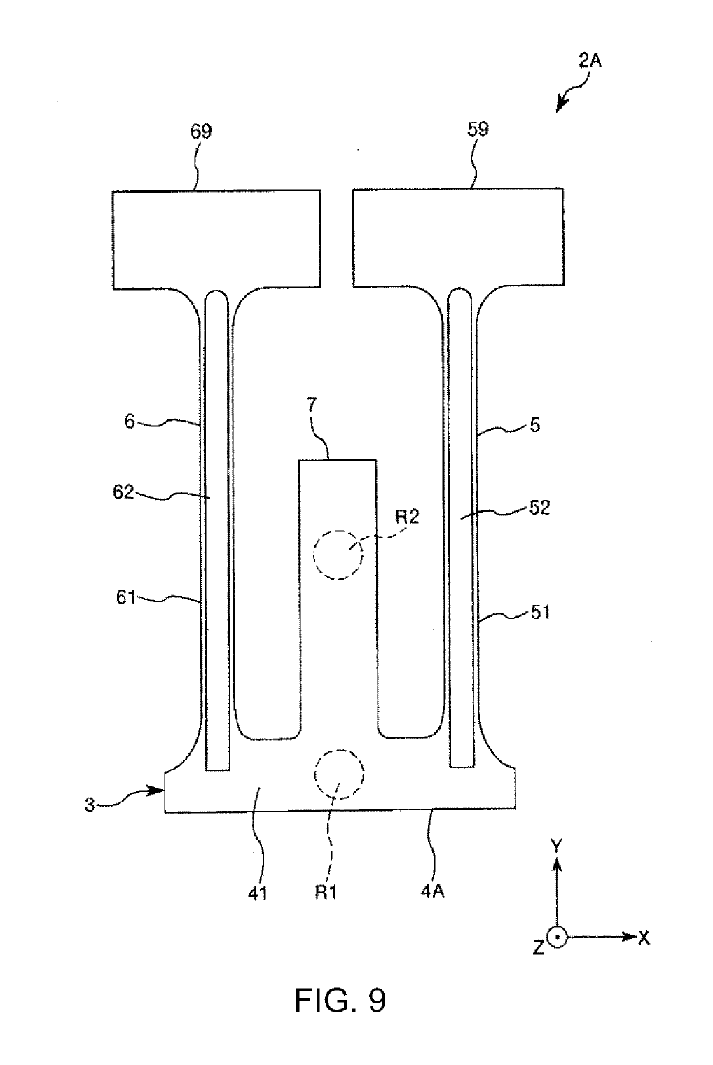

FIG. 9 is a top view of a resonator element included in the resonator according to the second embodiment of the invention.

Hereinafter, the resonator according to the second embodiment will be described focusing on the differences from the first embodiment described above, and a description of the same matters will be omitted.

The resonator according to the second embodiment of the invention is the same as that of the first embodiment described above except that the configuration of a resonator element is different. Meanwhile, the same components as in the first embodiment described above are denoted by the same reference numerals.

As shown in FIG. 9, a base portion 4A of a resonator element 2A is configured such that the width-decreasing portions 42 and 43 are omitted from the base portion 4 of the first embodiment described above and that only a main body 41 is included. With such a configuration, it is possible to reduce the total length of the resonator element, as compared with, for example, the resonator element 2 of the first embodiment described above.

Also in the second embodiment, the same effects as in the first embodiment described above can be exhibited.

### Third Embodiment

Next, a resonator according to a third embodiment of the invention will be described.

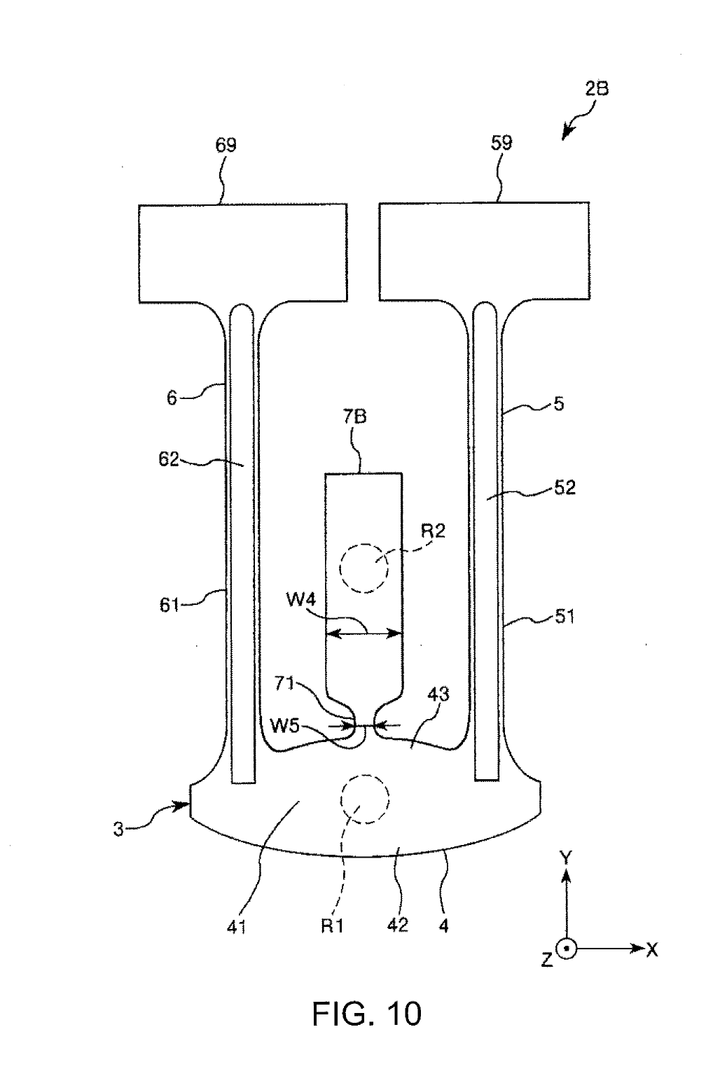

FIG. 10 is a top view of a resonator element included in a resonator according to a third embodiment of the invention.

Hereinafter, the resonator according to the third embodiment will be described focusing on the differences from the first embodiment described above, and a description of the same matters will be omitted.

The resonator according to the third embodiment of the invention is the same as that of the first embodiment described above except that the configuration of a resonator element is different. Meanwhile, the same components as in the first embodiment described above are denoted by the same reference numerals.

As shown in FIG. 10, a supporting arm 7B of a resonator element 2B has a narrow width portion 71 having a width (length in the X-axis direction) which is smaller than that of the distal end side, in the base end thereof. In addition, a second fixation portion R2 is provided in a region positioned on the distal end side with respect to the narrow width portion 71 of the supporting arm 7B. Due to the narrow width portion 71, it is possible to keep a resonance frequency in an X common mode (unnecessary vibration mode) away from a resonance frequency in an X reverse phase mode (main mode). For this reason, it is possible to reduce the mixing of an unnecessary vibration with a vibration in the main mode, and the resonator element 2B can exhibit excellent vibration characteristics. A width W5 of the narrow width portion 71 is not particularly limited, but it is preferable that the width is equal to or greater than 20% and be equal to or less than 50% of a width W4 of a portion on the distal end side with respect to the narrow width portion. Thus, the above-described effects are further improved, and a vibration of a base portion 4 is not likely to be transmitted by the supporting arm 7B.

In addition, it is preferable that the Young's modulus of a first fixation portion R1 is smaller than the Young's modulus of the second fixation portion R2. In this manner, it is possible to keep a resonance frequency in an X common mode (unnecessary vibration mode) away from a resonance frequency in an X reverse phase mode (main mode).

Also in the third embodiment, the same effects as in the first embodiment described above can be exhibited.

### Fourth Embodiment

Next, a resonator according to a fourth embodiment of the invention will be described.

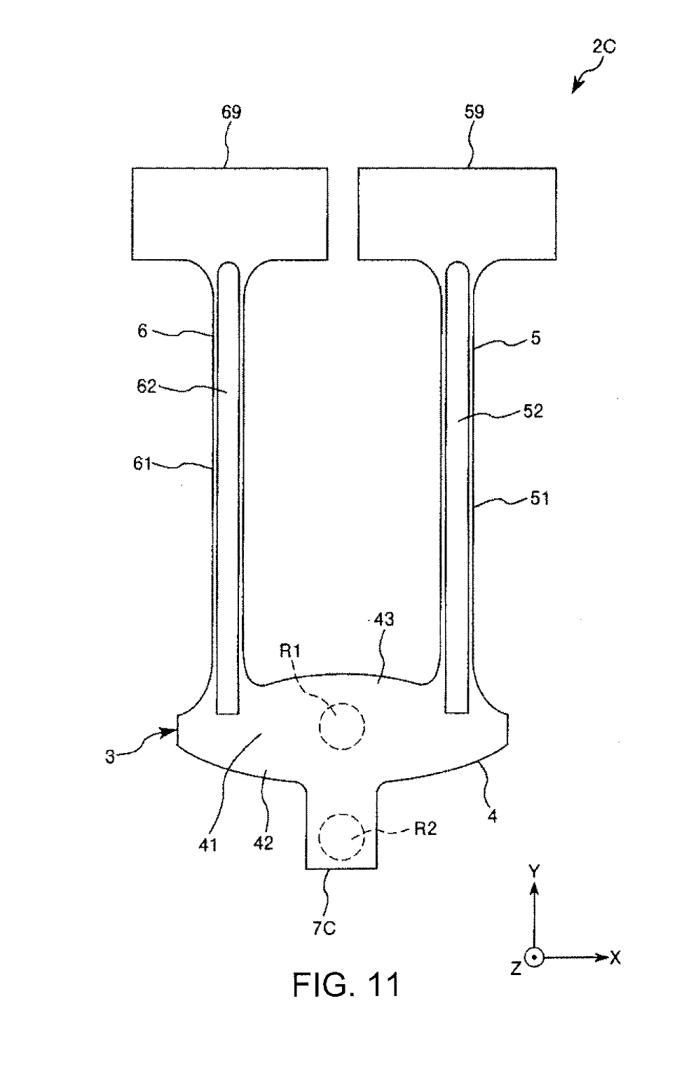

FIG. 11 is a top view of a resonator element included in the resonator according to the fourth embodiment of the invention.

Hereinafter, the resonator according to the fourth embodiment will be described focusing on the differences from the first embodiment described above, and a description of the same matters will be omitted.

The resonator according to the fourth embodiment of the invention is the same as that of the first embodiment described above except that the configuration of a resonator element is different. Meanwhile, the same components as in the first embodiment described above are denoted by the same reference numerals.

As shown in FIG. 11, a supporting arm 7C of a resonator element 2C extends toward the −Y-axis direction from the base end (the other end) of a base portion 4. In addition, a second fixation portion R2 is provided in one principal surface (principal surface on the −Z-axis side) of the supporting arm 7C.

Here, it is preferable that the Young's modulus of a first fixation portion R1 is smaller than the Young's modulus of the second fixation portion R2. In this manner, it is possible to keep a resonance frequency in an X common mode (unnecessary vibration mode) away from a resonance frequency in an X reverse phase mode (main mode).

Also in the fourth embodiment, the same effects as in the first embodiment described above can be exhibited.

### Fifth Embodiment

Next, a resonator according to a fifth embodiment of the invention will be described.

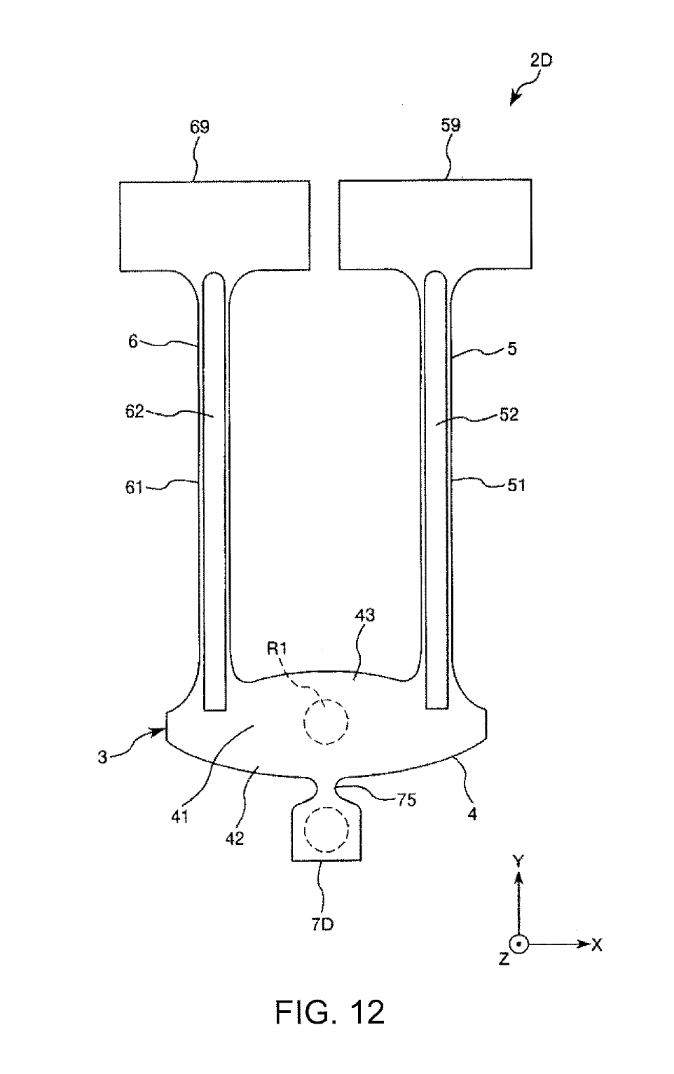

FIG. 12 is a top view of a resonator element included in the resonator according to the fifth embodiment of the invention.

Hereinafter, the resonator according to the fifth embodiment will be described focusing on the differences from the first embodiment described above, and a description of the same matters will be omitted.

The resonator according to the fifth embodiment of the invention is the same as that of the first embodiment described above except that the configuration of a resonator element is different. Meanwhile, the same components as in the first embodiment described above are denoted by the same reference numerals.

As shown in FIG. 12, a supporting arm 7D of a resonator element 2D extends toward the −Y-axis direction from the base end (the other end) of a base portion 4. In addition, the supporting arm 7D has a narrow width portion 75 having a width (length in the X-axis direction) which is smaller than that on the base end side, in the end on the base portion 4 side. A second fixation portion R2 is provided in a region positioned on the base end side with respect to the narrow width portion 75 of the supporting arm 7D. Due to the narrow width portion 75, it is possible to keep a resonance frequency in an X common mode (unnecessary vibration mode) away from a resonance frequency in an X reverse phase mode (main mode). For this reason, it is possible to reduce the mixing of an unnecessary vibration with a vibration in the main mode, and the resonator element 2D can exhibit excellent vibration characteristics.

In addition, it is preferable that the Young's modulus of a first fixation portion R1 is smaller than the Young's modulus of the second fixation portion R2. In this manner, it is possible to keep a resonance frequency in an X common mode (unnecessary vibration mode) away from a resonance frequency in an X reverse phase mode (main mode).

Also in the fifth embodiment, the same effects as in the first embodiment described above can be exhibited.

### Sixth Embodiment

Next, a resonator according to a sixth embodiment of the invention will be described.

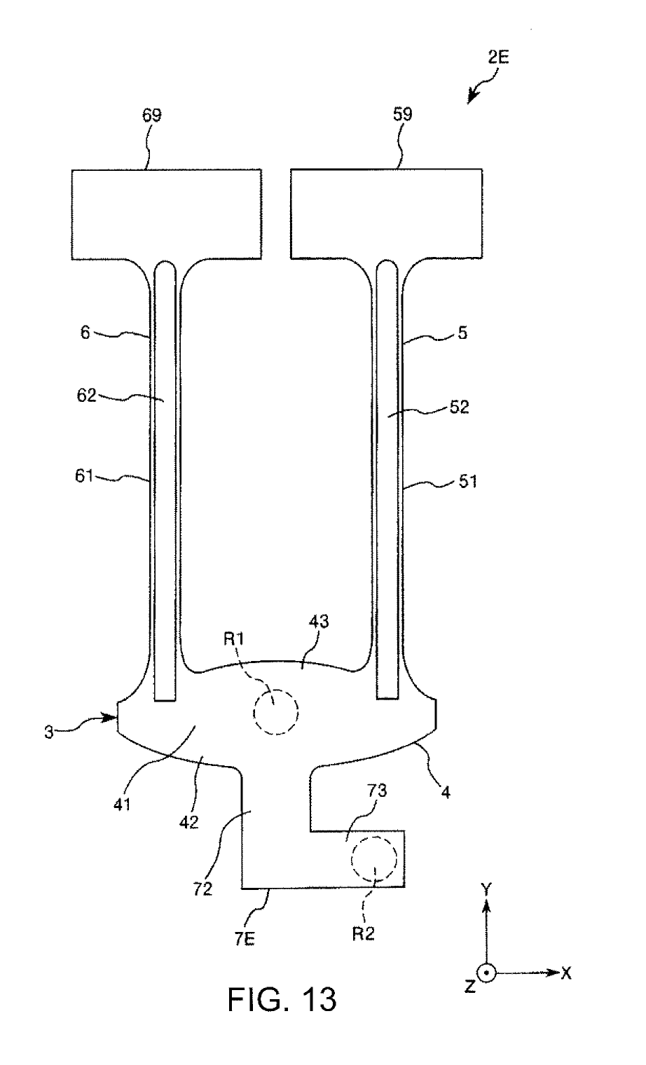

FIG. 13 is a top view of a resonator element included in the resonator according to the sixth embodiment of the invention.

Hereinafter, the resonator according to the sixth embodiment will be described focusing on the differences from the first embodiment described above, and a description of the same matters will be omitted.

The resonator according to the sixth embodiment of the invention is the same as that of the first embodiment described above except that the configuration of a resonator element is different. Meanwhile, the same components as in the first embodiment described above are denoted by the same reference numerals.

As shown in FIG. 13, a supporting arm 7E of a resonator element 2E includes a first portion 72 extending toward the −Y-axis direction from the base end of a base portion 4, and a second portion 73 extending in the X-axis direction from the first portion 72. In addition, a second fixation portion R2 is provided in one principal surface (principal surface on the −Z-axis side) of the second portion 73. The supporting arm 7E is configured in such a manner, and thus it is possible to increase a separation distance between the base portion 4 (first fixation portion R1) and the second fixation portion R2 without increasing the total length of the resonator element 2E in the Y-axis direction, as compared with, for example, the fourth and fifth embodiments described above. For this reason, it is possible to further separate the first and second fixation portions R1 and R2 from each other and to further reduce a vibration being transmitted from the base portion 4 to the second fixation portion R2.

In addition, it is preferable that the Young's modulus of the first fixation portion R1 is smaller than the Young's modulus of the second fixation portion R2. In this manner, it is possible to keep a resonance frequency in an X common mode (unnecessary vibration mode) away from a resonance frequency in an X reverse phase mode (main mode).

Also in the sixth embodiment, the same effects as in the first embodiment described above can be exhibited.

### Seventh Embodiment

Next, a resonator according to a seventh embodiment of the invention will be described.

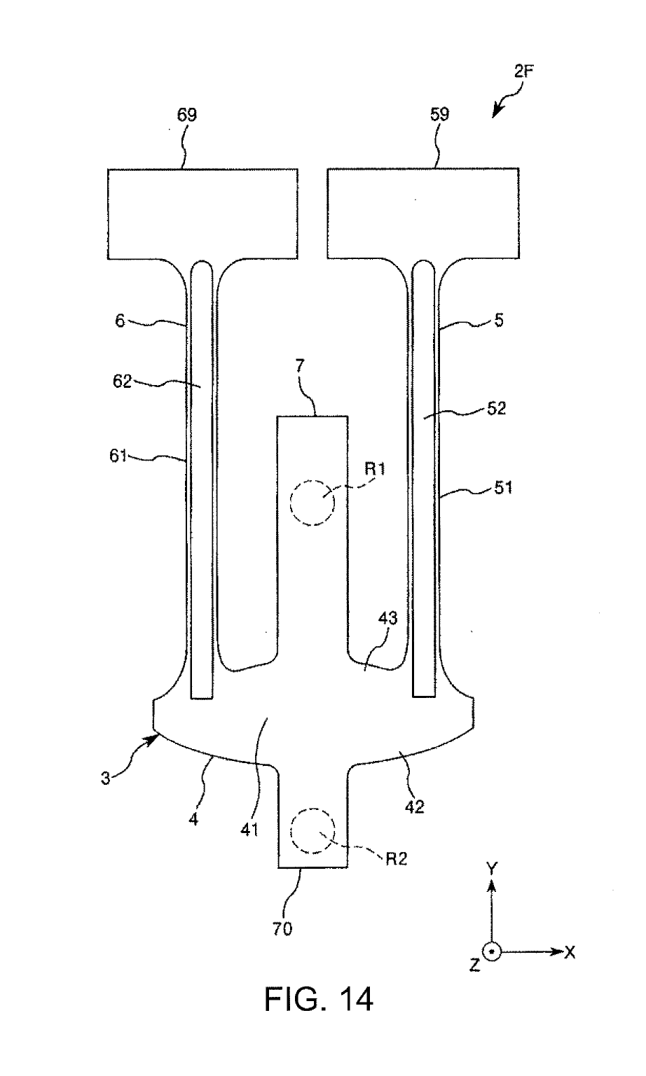

FIG. 14 is a top view of a resonator element included in the resonator according to the seventh embodiment of the invention.

Hereinafter, the resonator according to the seventh embodiment will be described focusing on the differences from the first embodiment described above, and a description of the same matters will be omitted.

The resonator according to the seventh embodiment of the invention is the same as that of the first embodiment described above except that the configuration of a resonator element is different. Meanwhile, the same components as in the first embodiment described above are denoted by the same reference numerals.

As shown in FIG. 14, a resonator element 2F includes a base portion 4, a pair of vibrating arms 5 and 6 extending in the +Y-axis direction from the distal end of the base portion 4, a supporting arm (first supporting arm) 7 extending in the +Y-axis direction from the distal end of the base portion 4, and a supporting arm (second supporting arm) 70 extending in the −Y-axis direction from the base end of the base portion 4. The base portion 4, the vibrating arms 5 and 6, and the supporting arms 7 and 70 are integrally formed from a quartz crystal substrate 3.

In addition, a first fixation portion R1 is provided in one principal surface (principal surface on the −Z-axis side) of the supporting arm 7, and a second fixation portion R2 is provided in one principal surface (principal surface on the −Z-axis side) of the supporting arm 70. According to such a configuration, it is possible to increase a separation distance between the first and second fixation portions R1 and R2, as compared with, for example, the first embodiment described above, and to reliably prevent contact between conductive adhesive members 11 and 12.

Also in the seventh embodiment, the same effects as in the first embodiment described above can be exhibited.

### Eighth Embodiment

Next, a resonator according to an eighth embodiment of the invention will be described.

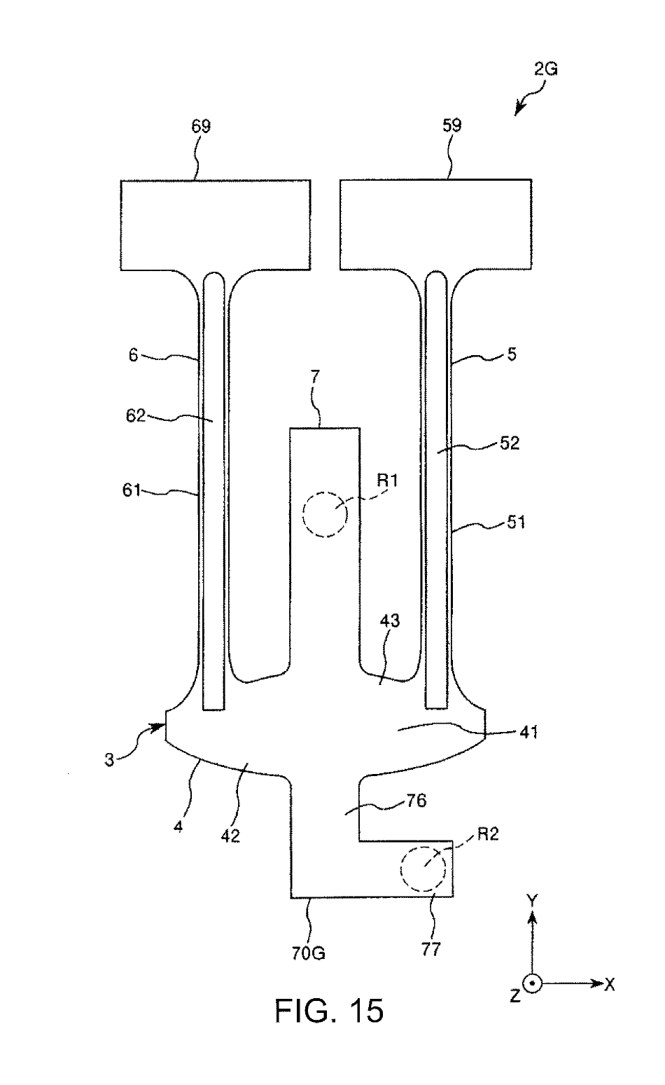

FIG. 15 is a top view of a resonator element included in the resonator according to the eighth embodiment of the invention.

Hereinafter, the resonator according to the eighth embodiment will be described focusing on the differences from the first embodiment described above, and a description of the same matters will be omitted.

The resonator according to the eighth embodiment of the invention is the same as that of the first embodiment described above except that the configuration of a resonator element is different. Meanwhile, the same components as in the first embodiment described above are denoted by the same reference numerals.

As shown in FIG. 15, a resonator element 2G includes a base portion 4, a pair of vibrating arms 5 and 6 extending in the +Y-axis direction from the distal end of the base portion 4, a supporting arm (first supporting arm) 7 extending in the +Y-axis direction from the distal end of the base portion 4, and a supporting arm (second supporting arm) 70G extending in the −Y-axis direction from the base end of the base portion 4. The base portion 4, the vibrating arms 5 and 6, and the supporting arms 7 and 70G are integrally formed from a quartz crystal substrate 3. In addition, the supporting arm 70G includes a first portion 76 extending toward the −Y-axis direction from the base end of the base portion 4, and a second portion 77 extending in the X-axis direction from the first portion 76. A first fixation portion R1 is provided in one principal surface (principal surface on the −Z-axis side) of the supporting arm 7, and a second fixation portion R2 is provided in one principal surface (principal surface on the Z-axis side) of the second portion 77. The supporting arm 70G is configured in this manner, and thus it is possible to increase a separation distance between the first and second fixation portions R1 and R2 without increasing the total length of the resonator element 2G in the Y-axis direction, as compared with, for example, the sixth embodiment described above.

Also in the eighth embodiment, the same effects as in the first embodiment described above can be exhibited.

### Ninth Embodiment

Next, a resonator according to a ninth embodiment of the invention will be described.

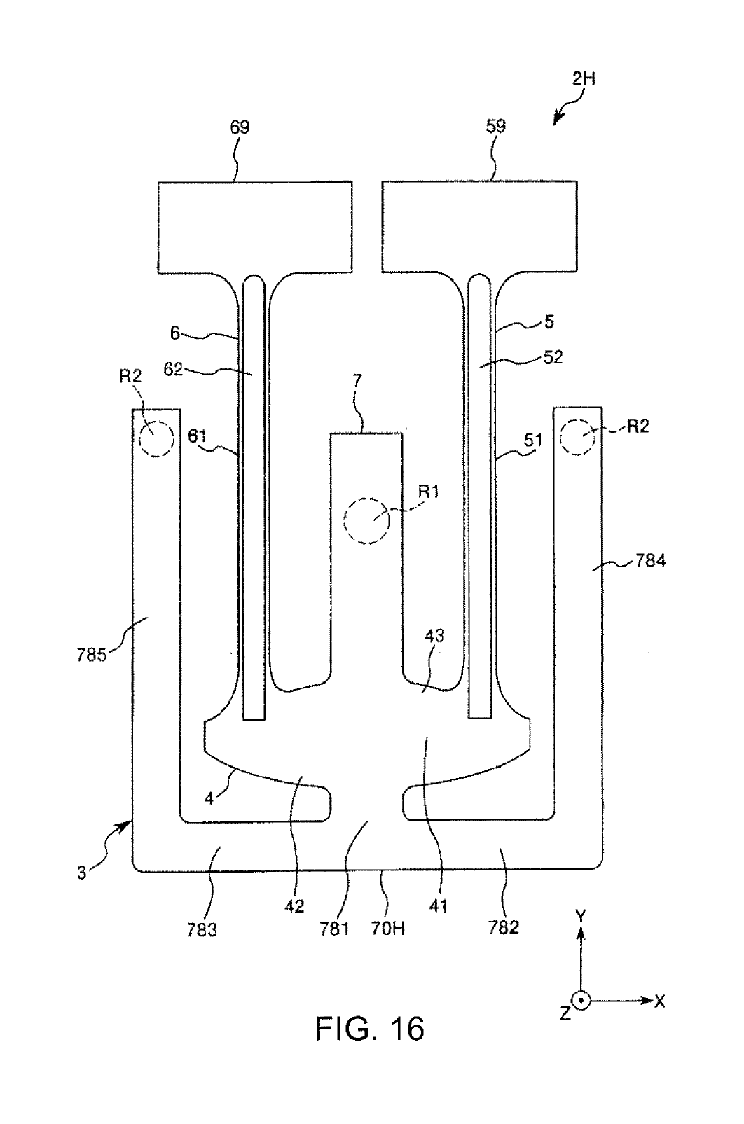

FIG. 16 is a top view of a resonator element included in the resonator according to the ninth embodiment of the invention.

Hereinafter, the resonator according to the ninth embodiment will be described focusing on the differences from the first embodiment described above, and a description of the same matters will be omitted.

The resonator according to the ninth embodiment of the invention is the same as that of the first embodiment described above except that the configuration of a resonator element is different. Meanwhile, the same components as in the first embodiment described above are denoted by the same reference numerals.

As shown in FIG. 16, a resonator element 2H includes a base portion 4, a pair of vibrating arms 5 and 6 extending in the +Y-axis direction from the distal end of the base portion 4, a supporting arm (first supporting arm) 7 extending in the +Y-axis direction from the distal end of the base portion 4, and a supporting arm (second supporting arm) 70H extending in the −Y-axis direction from the base end of the base portion 4. The base portion 4, the vibrating arms 5 and 6, and the supporting arms 7 and 70H are integrally formed from a quartz crystal substrate 3. In addition, the supporting arm 70H includes a branch portion 781 which extends from the base end of the base portion 4 and is branched in the X-axis direction, connecting arms 782 and 783 extending from the branch portion 781 to both sides in the X-axis direction, and arm portions 784 and 785 extending from the distal ends of the connecting arms 782 and 783 to the vibrating arms 5 and 6 sides in the Y-axis direction. A first fixation portion R1 is provided in one principal surface (principal surface on the −Z-axis side) of the supporting arm 7, and a second fixation portion R2 is provided in one principal surface (principal surface on the −Z-axis side) of each of the arm portions 784 and 785. Meanwhile, in this embodiment, a second connection electrode 82 may be provided in any one of the two second fixation portions R2.

Also in the ninth embodiment, the same effects as in the first embodiment described above can be exhibited.

Meanwhile, in the above-described embodiments and modified examples, quartz crystal is used as the material of the resonator element. However, the invention is not limited thereto, and it is possible to use, for example, an oxide substrate such as aluminum nitride (AlN), lithium niobate (LiNbO₃), lithium tantalite (LiTaO₃), lead zirconate titanate (PZT), lithium tetraborate (Li₂B₄O₇), or langasite (La₃Ga₅SiO₁₄) a laminated piezoelectric substrate configured by laminating a piezoelectric material such as aluminum nitride, tantalum pentoxide (Ta₂O₅) and the like on a glass substrate, piezoelectric ceramics, and the like.

In addition, it is possible to form a resonator element using a material other than a piezoelectric material. For example, it is also possible to form a resonator element using a silicon semiconductor material. In addition, a vibration (driving) method of the resonator element is not limited to a piezoelectric driving method. It is also possible to exhibit the configuration of the invention and the effects thereof also in resonator elements such as an electrostatic driving type using an electrostatic force and a Lorentz driving type using a magnetic force, in addition to a piezoelectric driving type using a piezoelectric substrate. In addition, the terms used in the specification or the drawings at least once together with a different term having a broader or similar meaning can be replaced with a different term in any portion of the specification or the drawings.

### 2. Oscillator

Next, an oscillator to which the resonator element according to the invention (oscillator according to the invention) is applied will be described.

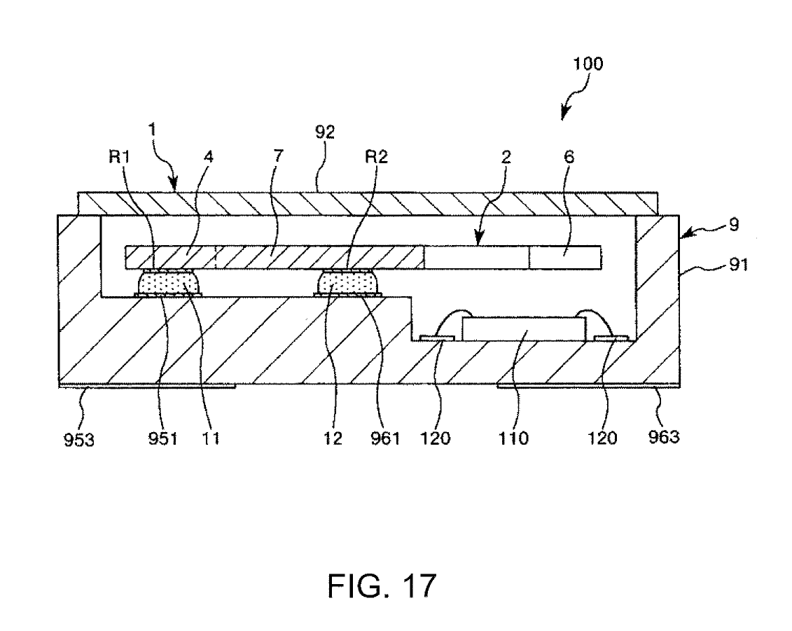

FIG. 17 is a cross-sectional view showing an oscillator according to a preferred embodiment of the invention.

An oscillator 100 shown in FIG. 17 includes a resonator 1 and an IC chip 110 for driving the resonator element 2. Hereinafter, the oscillator 100 will be described focusing on the differences from the resonator described above, and a description of the same matters will be omitted.

As shown in FIG. 17, in the oscillator 100, the IC chip 110 is fixed to the concave portion 911 of the base 91. The IC chip 110 is electrically connected to a plurality of internal terminals 120 formed on the bottom surface of the concave portion 911. The plurality of internal terminals 120 include terminals connected to the connecting terminals 951 and 961 and terminals connected to the external terminals 953 and 963. The IC chip 110 has an oscillation circuit for controlling the driving of the resonator element 2. When the resonator element 2 is driven by the IC chip 110, it is possible to extract a signal having a predetermined frequency.

### 3. Electronic Device

Next, an electronic device to which the resonator element according to the invention is applied (electronic device according to the invention) will be described.

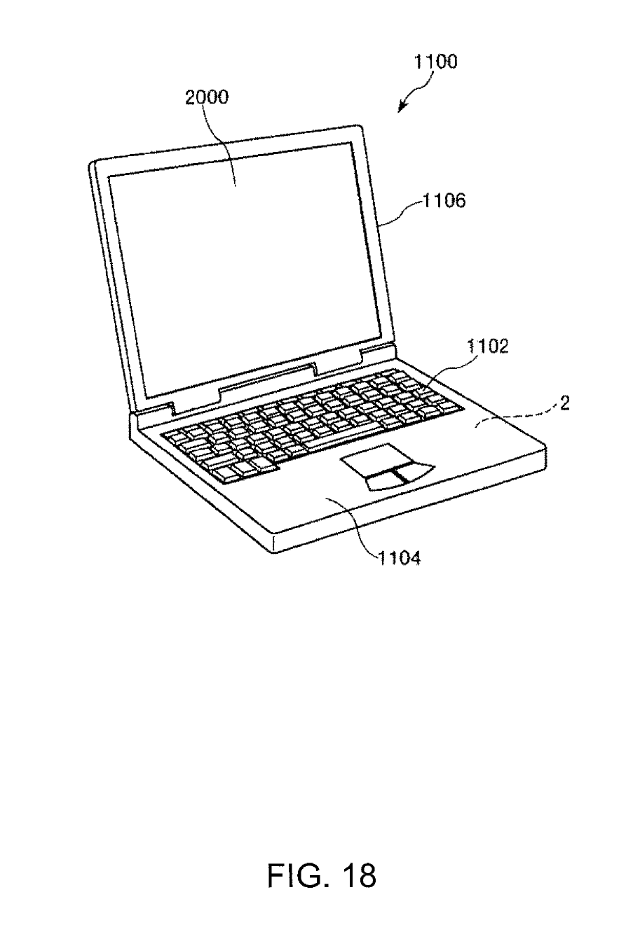

FIG. 18 is a perspective view showing a configuration of a mobile (or notebook) personal computer to which the electronic device including the resonator element according to the invention is applied. In FIG. 18, a personal computer 1100 is configured to include a main body 1104 having a keyboard 1102 and a display unit 1106 having a display portion 2000, and the display unit 1106 is supported so as to be rotatable with respect to the main body 1104 through a hinge structure. The resonator element 2 that functions as a filter, a resonator, a reference clock, and the like is built into the personal computer 1100.

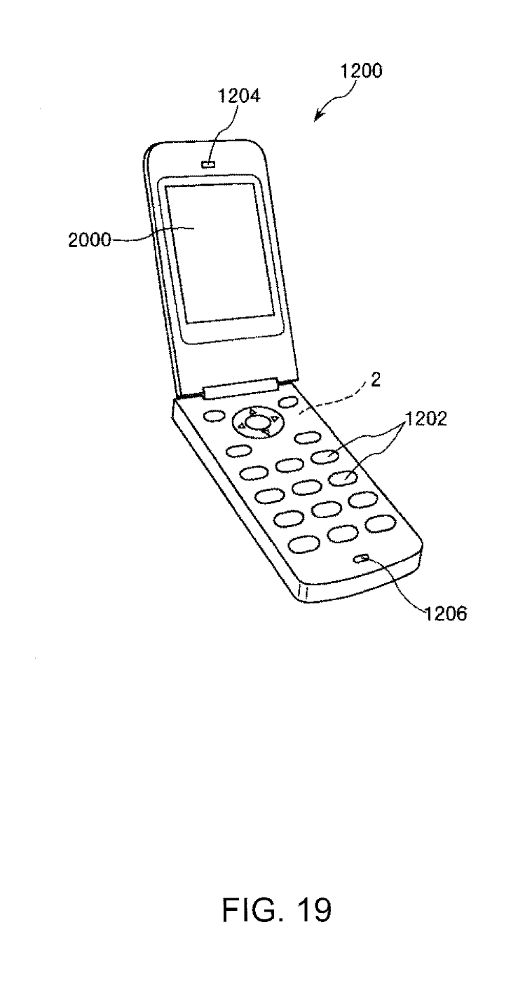

FIG. 19 is a perspective view showing the configuration of a mobile phone (PHS is also included) to which an electronic device including the resonator element according to the invention is applied. In FIG. 19, a mobile phone 1200 includes a plurality of operation buttons 1202, an earpiece 1204, and a mouthpiece 1206, and a display portion 2000 is disposed between the operation buttons 1202 and the earpiece 1204. The resonator element 2 that functions as a filter, a resonator, and the like is built into the mobile phone 1200.

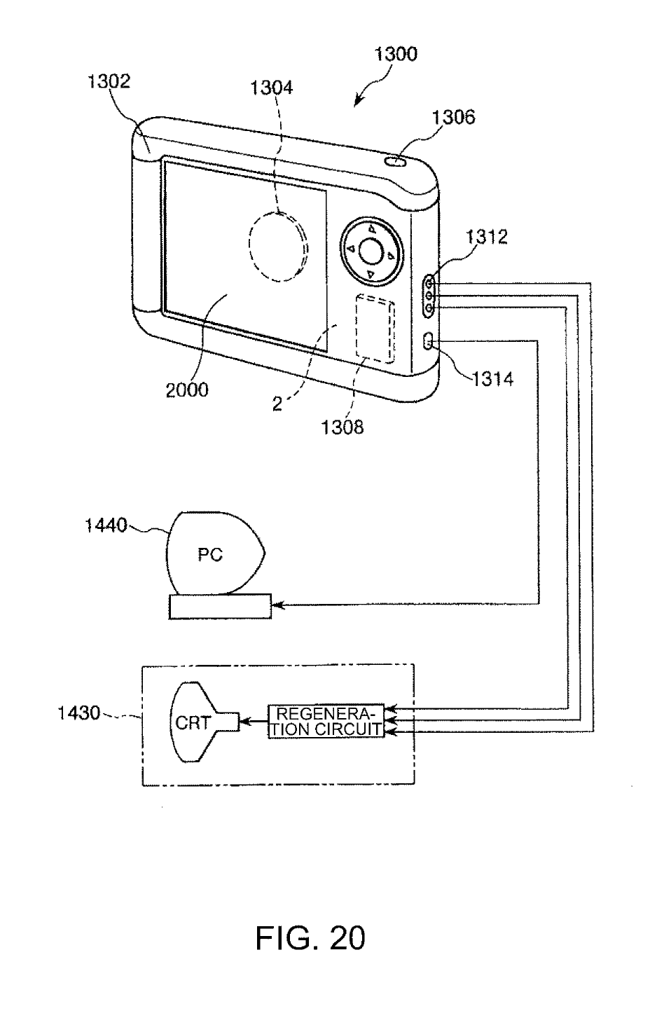

FIG. 20 is a perspective view showing the configuration of a digital still camera to which an electronic device including the resonator element according to the invention is applied. Meanwhile, connection with an external device is simply shown in FIG. 20. Here, a silver halide photography film is exposed to light according to an optical image of a subject in a typical camera, while the digital still camera 1300 generates an imaging signal (image signal) by performing photoelectric conversion of an optical image of a subject using an imaging element, such as a charge coupled device (CCD).

A display portion is provided on the back of a case (body) 1302 in the digital still camera 1300, so that display based on the imaging signal of the CCD is performed. The display portion functions as a viewfinder that displays a subject as an electronic image. In addition, a light receiving unit 1304 including an optical lens (imaging optical system), a CCD, and the like is provided on the front side (back side in FIG. 23) of the case 1302.

When a photographer checks a subject image displayed on the display portion and presses a shutter button 1306, an imaging signal of the CCD at that point in time is transferred and stored in a memory 1308. In addition, in the digital still camera 1300, a video signal output terminal 1312 and an input/output terminal for data communication 1314 are provided on the side surface of the case 1302. As shown in FIG. 20, a television monitor 1430 is connected to the video signal output terminal 1312 and a personal computer 1440 is connected to the input/output terminal for data communication 1314 when necessary. Further, an imaging signal stored in the memory 1308 may be output to the television monitor 1430 or the personal computer 1440 by a predetermined operation. The resonator element 2 that functions as a filter, a resonator, and the like is built into the digital still camera 1300.

Meanwhile, the electronic device including the resonator element according to the invention can be applied not only to the personal computer (mobile personal computer) shown in FIG. 18, the mobile phone shown in FIG. 19, and the digital still camera shown in FIG. 20 but also to an ink jet type discharge apparatus (for example, an ink jet printer), a laptop type personal computer, a television, a video camera, a video tape recorder, a car navigation apparatus, a pager, an electronic organizer (an electronic organizer with a communication function is also included), an electronic dictionary, an electronic calculator, an electronic game machine, a word processor, a workstation, a video phone, a television monitor for security, electronic binoculars, a POS terminal, medical equipment (for example, an electronic thermometer, a sphygmomanometer, a blood sugar meter, an electrocardiographic measurement device, an ultrasonic diagnostic apparatus, and an electronic endoscope), a fish detector, various measurement apparatuses, instruments (for example, instruments for vehicles, aircraft, and ships), and a flight simulator.

### 4. Moving Object

Next, a moving object to which the resonator element according to the invention (moving object according to the invention) is applied will be described.

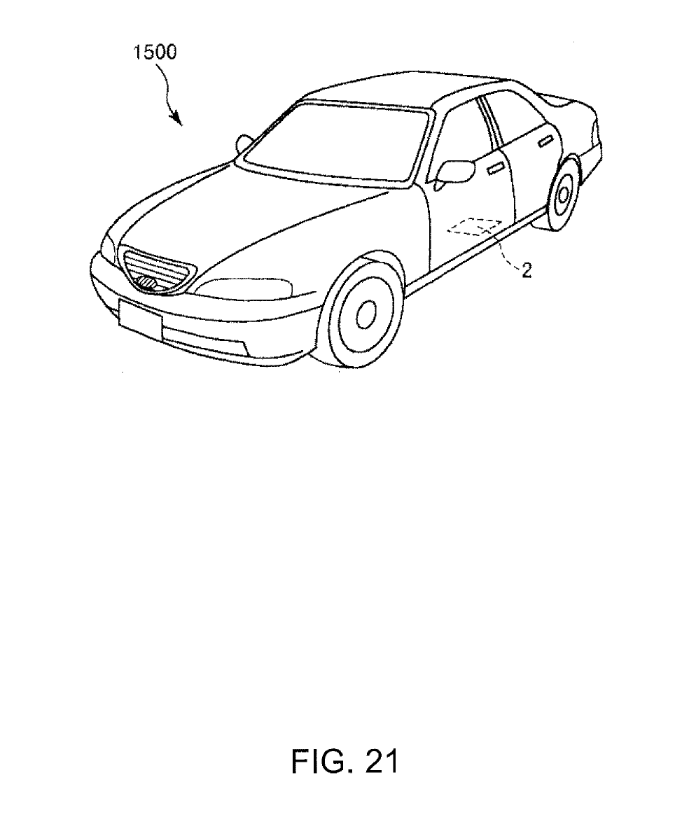

FIG. 21 is a perspective view schematically showing a vehicle as an example of the moving object according to the invention. The resonator element 2 is mounted in a vehicle 1500. The resonator element 2 can be widely applied to an electronic control unit (ECU), such as a keyless entry, an immobilizer, a car navigation system, a car air-conditioner, an anti-lock brake system (ABS), an airbag, a tire pressure monitoring system (TPMS), an engine control, a battery monitor of a hybrid vehicle or an electric vehicle, and a vehicle body position control system.

While the resonator element, the resonator, the oscillator, the electronic device, and the moving object according to the invention have been described with reference to the illustrated embodiments, the invention is not limited thereto, and the configuration of each portion may be replaced with an arbitrary configuration having the same function. In addition, other arbitrary structures may be added to the invention. In addition, the embodiments described above may be appropriately combined.

Meanwhile, in the above-described embodiments and modified examples, quartz crystal is used as the material of the resonator element. However, the invention is not limited thereto, and it is possible to use, for example, an oxide substrate such as aluminum nitride (AlN), lithium niobate (LiNbO₃), lithium tantalate (LiTaO₃), lead zirconate titanate (PZT), lithium tetraborate (Li₂B₄O₇), or langasite (La₃Ga₅SiO₁₄), a laminated piezoelectric substrate configured by laminating a piezoelectric material such as aluminum nitride, tantalum pentoxide (Ta₂O₅), and the like on a glass substrate, piezoelectric ceramics, and the like.

In addition, it is possible to form a resonator element using a material other than a piezoelectric material. For example, it is also possible to form a resonator element using a silicon semiconductor material. In addition, a vibration (driving) method of the resonator element is not limited to a piezoelectric driving method. It is also possible to exhibit the configuration of the invention and the effects thereof also in resonator elements such as an electrostatic driving type using an electrostatic force and a Lorentz driving type using a magnetic force, in addition to a piezoelectric driving type using a piezoelectric substrate. In addition, the terms used in the specification or the drawings at least once together with a different term having a broader or similar meaning can be replaced with a different term in any portion of the specification or the drawings.

What is claimed is:

1. A resonator element comprising:
a base portion;
a pair of vibrating arms that extend in a first direction from one side of the base portion and are arranged in a second direction perpendicular to the first direction;
a supporting arm that extends from the base portion,
a first fixing portion provided in one principal surface of the base portion; and
a second fixing portion provided in one principal surface of the supporting arm,
the first fixing portion and the second fixing portion being attached to an object through connection members.

2. The resonator element according to claim 1, wherein the supporting arm extends in the first direction from the one side of the base portion and is disposed between the pair of vibrating arms.

3. The resonator element according to claim 2, wherein the supporting arm extends from an other side opposite to the one side of the base portion when seen in a plan view.

4. The resonator element according to claim 3,
the supporting arm further including:
a first portion that extends along the first direction from the other side; and
a second portion that extends along the second direction from the first portion,
wherein the second fixing portion is provided in the second portion.

5. The resonator element according to claim 1, wherein the first fixing portion intersects a virtual straight line along the first direction which passes through a center of the base portion in the second direction between the pair of vibrating arms, when seen in a plan view.

6. The resonator element according to claim 1, wherein the base portion includes a width-decreasing portion having a width along the second direction which decreases in a continuous manner or in a stepwise manner as a distance from the first fixingportion increases along the first direction, when seen in a plan view.

7. A resonator element comprising:
a base portion;
a pair of vibrating arms that extend in a first direction from one end of the base portion and are arranged in a second direction perpendicular to the first direction;
a first supporting arm that extends in the first direction from the one side of the base portion and is disposed between the pair of vibrating arms;
a second supporting arm that extends from the other side opposite to the one side of the base portion, when seen in a plan view;
a first fixing portion provided in one principal surface of the first supporting arm; and
a second fixing portion provided in one principal surface of the second supporting arm,
the first fixing portion and the second fixing portion being attached to an object through connection members.

8. The resonator element according to claim 7, wherein the base portion includes a width-decreasing portion having a width along the second direction which decreases in a continuous manner or in a stepwise manner as a distance from the first fixing portion increases along the first direction, when seen in a plan view.

9. A resonator comprising:
the resonator element according to claim 1; and
a package that accommodates the resonator element.

10. A resonator comprising:
the resonator element according to claim 2; and
a package that accommodates the resonator element.

11. A resonator comprising:
the resonator element according to claim 3; and
a package that accommodates the resonator element.

12. An oscillator comprising:
the resonator element according to claim 1; and
an oscillation circuit.

13. An oscillator comprising:
the resonator element according to claim 2; and
an oscillation circuit.

14. An oscillator comprising:
the resonator element according to claim 3; and
an oscillation circuit.

15. An electronic device comprising the resonator element according to claim 1.

16. An electronic device comprising the resonator element according to claim 2.

17. An electronic device comprising the resonator element according to claim 3.

18. A moving object comprising the resonator element according to claim 1.

19. A moving object comprising the resonator element according to claim 2.

20. A moving object comprising the resonator element according to claim 3.

21. A resonator element comprising:
a base portion;
a pair of vibrating arms that extend in a first direction from a first side of the base portion and are arranged in a second direction perpendicular to the first direction;
a supporting arm that extends from one side of the base portion;
a first fixing portion provided in a principal surface of a central area of the base portion; and
a second fixing portion provided in a principal surface of an end of the supporting arm,
the first fixing portion and the second fixing portion being attached to an object through connection members.
